(19) United States
(12) Patent Application Publication
(10) Pub. No.: US 2026/0093859 A1
(43) Pub. Date: Apr. 2, 2026

(54) ADVERSARIAL CAMOUFLAGE AND DECOY GENERATION ACROSS VISUAL AND NON-VISUAL MODALITIES

(71) Applicant: The Adversarial Company, Inc., Los Angeles, CA (US)

(72) Inventor: Patrick Brian Bentley, JR., Los Angeles, CA (US)

(21) Appl. No.: 19/342,427

(22) Filed: Sep. 26, 2025

Related U.S. Application Data
(60) Provisional application No. 63/699,808, filed on Sep. 27, 2024.
(60) Provisional application No. 63/821,871, filed on Jun. 11, 2025.

(51) Int. Cl. G06F 30/13; G06T 15/20

(52) U.S. Cl. CPC G06F 30/13; G06T 15/20

(57) ABSTRACT

Disclosed is a system to generate an adversarial pattern. The system receives an input specifying data describing a target object, an objective indicating whether to reduce detectability of the target object or to induce a false detection of a target type, and context parameters. The system generates candidate adversarial patterns for the target object using an AI-based generative algorithm. Each candidate adversarial pattern represents a potential solution for achieving the objective under context parameters. The system simulates a representation of the target object with candidate adversarial pattern in a virtual environment that models a plurality of sensor modalities. The simulation may use machine learning object detection models. The system analyzes the target object and generates, for each target object, a performance metric for ranking the candidate adversarial pattern based on an effectiveness of the simulated representation. The candidate adversarial pattern with highest rank is generated as an optimized adversarial pattern.

### CROSS REFERENCE TO RELATED APPLICATIONS

This application claims the benefit of, and priority to, U.S. Provisional Application No. 63/699,808, filed Sep. 27, 2024, and U.S. Provisional Application No. 63/821,871, filed Jun. 11, 2025, the contents of each of which is incorporated by reference in its entirety.

### TECHNICAL FIELD

The disclosure relates to the field of adversarial optimization techniques for machine perception systems, and particularly, in an adaptive multi-modal system and method for generating adversarial signals and patterns across both visual and non-visual sensor modalities.

### BACKGROUND

Advances in computer vision, sensing, and artificial intelligence have made it increasingly feasible to automatically detect and recognize objects using machine learning models. Modern surveillance systems, autonomous vehicles, and military targeting platforms often employ deep neural network detectors to identify people, vehicles, weapons, and other assets from visual imagery, thermal infrared feeds, LiDAR point clouds, radar scans, and other sensor data. However, alongside the proliferation of AI-based detection systems, it has become evident that these models are vulnerable to adversarial examples—inputs deliberately perturbed to mislead the model's predictions. Researchers have demonstrated both digital adversarial attacks (where small pixel perturbations in an image cause misclassification) and physical adversarial attacks (where objects adorned with specially crafted patterns, sometimes called adversarial patches, cause detectors to fail to detect the object or to misidentify it). These findings underscore a new opportunity and threat, which is the same AI that enables advanced sensing may be deceived under the right conditions.

Existing attempts at physical adversarial camouflage have shown the potential to fool AI vision systems, but they suffer from critical limitations. Many patterns effective against machine-learning detectors appear as unnatural, high-contrast graphics or random noise that, while confusing to a computer vision model, are easily noticed by a human observer. For example, a shirt or vehicle wrap with a random-looking, high-frequency adversarial pattern might cause an AI-based camera to overlook a person entirely, but that same pattern appears conspicuous and bizarre to human eyes. This defeats the purpose of camouflage in practical scenarios because an effective modern solution must fool machines without alerting human observers. Traditional camouflages used by militaries or in nature rely on naturalistic textures and colors to blend into the environment, but such conventional camouflage is not designed to defeat AI-based detectors. There is thus a gap between patterns that fool machines and those that fool humans. A truly effective modern stealth technique must address both aspects simultaneously.

### BRIEF DESCRIPTION OF DRAWINGS

The disclosed embodiments have other advantages and features which will be more readily apparent from the detailed description, the appended claims, and the accompanying figures (or drawings). A brief introduction of the figures is below.

FIG. 1A illustrates and example stealth adversarial artificial intelligence (AI) system according to one embodiment.

FIG. 1B illustrates an example decoy adversarial artificial intelligence (AI) system in accordance with one embodiment.

FIG. 2 is a schematic block diagram of an example adaptive adversarial pattern generation system architecture according to one embodiment.

FIG. 3 is a flowchart illustrating an example process for generating and deploying an adversarial camouflage pattern (stealth mode) for concealing a real object from machine vision detectors in accordance with one embodiment.

FIG. 4 is a flowchart illustrating an example process for generating and deploying an adversarial decoy pattern or signal (decoy mode) for causing false target detection by machine perception systems in accordance with one embodiment.

FIG. 5 illustrates an example machine to read and execute computer readable instructions in accordance with one embodiment.

### DETAILED DESCRIPTION

The Figures (FIGS.) and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

### Introductory Overview

In the disclosed configuration “stealth mode” or “camouflage mode” may be used to refer to the adversarial camouflage functionality, for example, concealing physical objects (e.g., real world objects). Also in the disclosed configuration, “decoy mode” may refer to the adversarial decoy functionality, for example, creating or generating false target physical objects. For convenience, the intended objective of a given adversarial pattern, i.e., stealth or decoy, may be referred to as a pattern intent.

The following detailed description is organized by first presenting the overall system architecture and shared pipeline applicable to both modes, then describing specific embodiments and considerations for the stealth (camouflage) and decoy modes, followed by discussions of design constraints, deployment, verification, and example use cases. It should be understood that the various features described for one mode (stealth or decoy) may be applicable to the other, except where the context indicates otherwise.

Further, the disclosed configuration provides a system (e.g., an apparatus and method) for generating adversarial patterns across visual and non-visual modalities using that architecture that allows for modulation of machine perception. The adversarial patterns that are generated may be output as physical patterns or electronic signal patterns The generated adversarial patterns may be applied across physical, electronic, and digital domains. Integrating the adversarial patterns across such domains in real-world deployments on various target objects (e.g., devices and media) enables concealing (or cloaking (e.g., camouflage or signal noise)) of such objects when a stealth mode is desired or identification of an object in decoy mode that is not intended to be an object of interest. Hence, the generation and deployment of adversarial patterns influences adversarial perception systems processing of data from sensors as perceived (or registered) by those sensors, e.g., visual or emitted data. This enables counter-detection measures against adversarial perception machines (and systems) to conceal real assets (stealth application), induce (or create) decoy patterns (e.g., visual or emitted) to produce false targets (deception (or decoy) application), and enhancing the visibility of selected objects to machine sensors (visibility maximization), across a variety of sensor modalities.

Machine perception may be, for example, a computing device with an artificial intelligence (AI) and machine learning (ML) architecture that is configured to review data of an environment to detect presence of an object in that environment. The detection may be, for example, visual, thermal, acoustic, or radar. Machine perception may be used with human input in which the human also may augment an analysis by the machine. Modulating machine perception in an adversarial computing system may include, for example, how an AI/ML architecture perceives an environment that it is analyzing and also may include hiding or deceiving what a human or machine observer may observe or not observe in an environment.

In some embodiments, the adversarial pattern generation system described herein may be implemented as part of a broader core platform that integrates multiple modules (sometimes referred to as an “integrator” platform for adaptive adversarial countermeasures). The system architecture and modules described below correspond to components of such a platform. For example, modules for pattern generation, multi-modal simulation, detector ensembles, and optimization may be shared with the core integrator framework. The present description focuses on the aspects of generating adversarial patterns across visual and non-visual modalities using that architecture. Modules or functionality that are common with the core platform are referenced for context.

### Configuration Overview

The disclosed configuration provides a system (e.g., an apparatus and method) for a unified adaptive adversarial optimization system for modulating the detectability of objects to artificial intelligence (AI) (including machine learning (ML)) and other machine perception systems. Modulating machine perception in an adversarial computing system may include how an AI/ML architecture perceives an environment that it is analyzing and also may include hiding or deceiving what a human observer may observe or not observe in an environment.

The system generates and deploys adversarial patterns or other sensor stimuli to reduce detectability of an asset, for example, rendering a real object effectively “invisible” or unrecognizable to AI detectors. It also may produce a decoy signature to increase detectability in a controlled way causing a non-existent or irrelevant object to be falsely detected by an adversarial AI system. Unlike traditional static camouflage or pre-designed decoys, the system employs an AI-driven technique to generate context-aware, machine-optimized patterns that deceive or manipulate AI detection models while remaining plausible and inconspicuous in the real world. The configuration protects real physical or digital assets from being detected by machine learning (ML) algorithms and may project false targets that mislead those AI algorithms, without alerting human observers via any obvious anomalies.

The disclosed configuration may be embodied in various forms, including a computer-implemented system (as well as method and a non-transitory computer readable storage medium comprising stored instructions) of adversarial pattern/signal generation for stealth or deception and the adversarial artifacts or manufactured products created by the system, such as physical patterned materials, devices, or prepared signals used to achieve the stealth or decoy effect.

### Stealth Adversarial AI System Overview

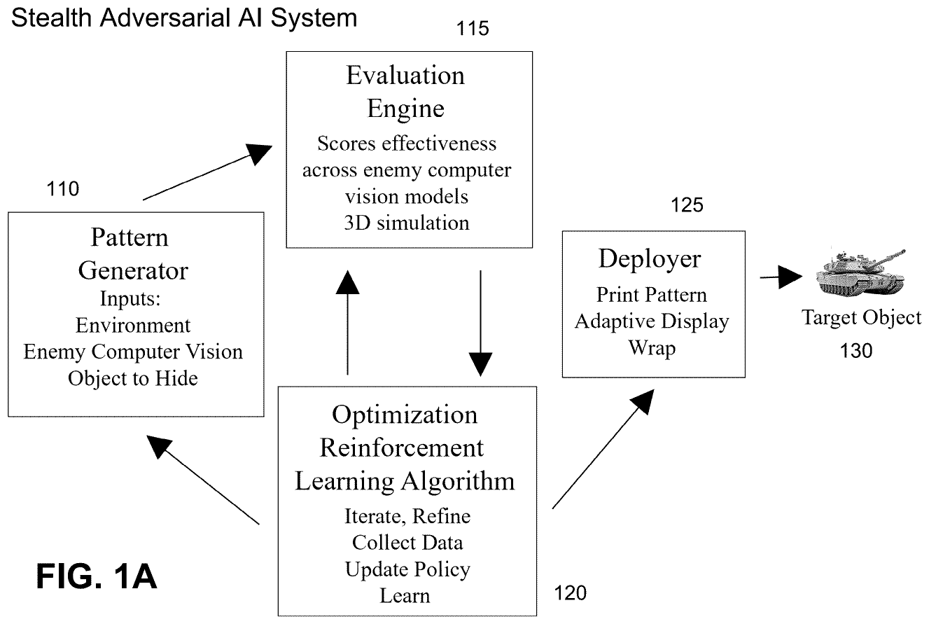

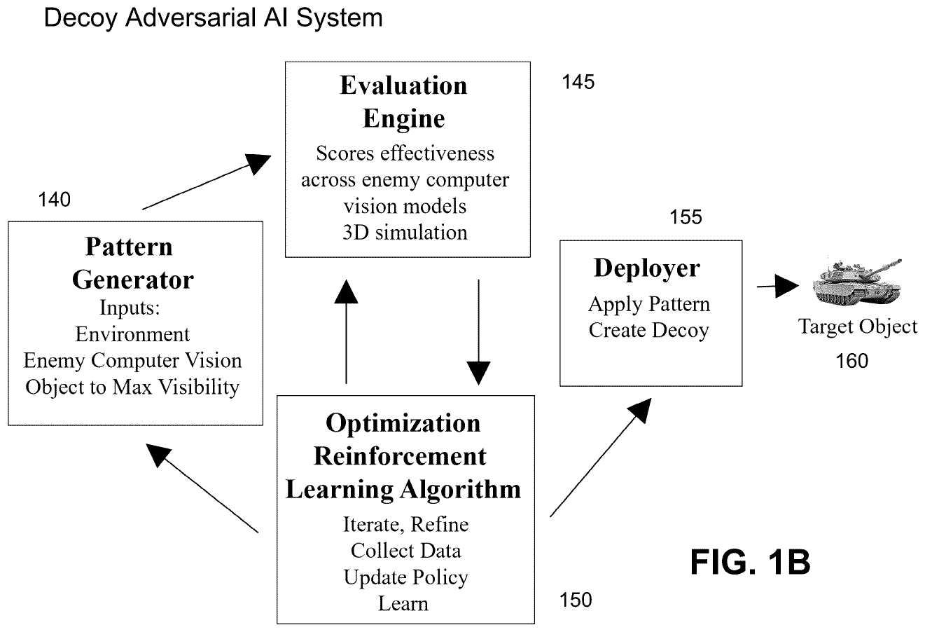

FIG. 1A illustrates and example stealth adversarial artificial intelligence (AI) system according to one embodiment. By way of example, a system adaptively generates an adversarial camouflage pattern to reduce the detectability of a target object. The target object may be a physical object or a digital display (e.g., electronic display or screen).

The system includes a pattern generator 110, an evaluation engine 115, an optimization reinforcement learning algorithm 120, and a deployment module 125. The pattern generator may include a generative model (e.g., a generative adversarial network, variational autoencoder, diffusion model, evolutionary algorithm, or other AI-based generator) to synthesize an initial set of candidate camouflage patterns. These candidate patterns may be constrained or guided by input parameters. For example, a user or operator may specify a desired camouflage style or provide data about the operational environment so that the generated pattern incorporates colors, textures, and features drawn from that environment so that adversarial AI detection systems are unable to detect the item. The pattern generator 110 may use one or more object detection algorithms to generate a pattern based on the inputs to generate a patterned image that will be applied to a physical object. The pattern image may be generated as an output for application on a target object 130. The output may be a physical print (e.g., vinyl sheets), a guidance document for how to apply a specified image, or an electronic image that may be uploaded onto a display medium on the physical object.

The evaluation engine 115 is configured to evaluate detectability of an object by scoring the effectiveness of a generated patterns against simulations of an adversarial AI machine vision model (e.g., a three-dimensional simulation). For example, an ensemble of AI detectors (covering various model architectures and sensor types) may be used to simulate how an adversary's perception system would perceive the object with that pattern. A performance metric (such as detection confidence scores from each model) is computed for each pattern, indicating how successfully it avoids detection by the ensemble.

The optimization reinforcement learning engine 120 of the system iteratively refines the patterns. For example, an optimization reinforcement learning engine 120 modifies the candidates to improve their stealth performance, guided by an optimization technique such as an evolutionary algorithm (which evolves a population of patterns over successive generations via selection, crossover, and mutation) or reinforcement learning (which treats pattern generation as an agent being rewarded for evasion success). This information may be fed back to the pattern generator 120. This generate-evaluate-optimize loop repeats until an optimized camouflage pattern is obtained that minimizes the probability of the target object being detected by any of the ensemble models. Importantly, during this process the candidate patterns can also be checked against human-visibility criteria. Further, it may filter out any designs that look conspicuously artificial or otherwise draw unwanted attention from human observers.

The deployer module 125 generates a final adversarial camouflage pattern. The pattern may be a physical print (e.g., vinyl sheets or a wrap), a document describing how to apply a specified image, or an electronic image that may be uploaded onto a display medium on the physical object. The pattern is generated is meant to deceive machine detectors while remaining contextually natural to humans. Each candidate pattern is then virtually or physically applied to a model of the target object 130, e.g. a 3D digital model or a set of images of the object, for verification and/or deployment in a field setting.

### Decoy Adversarial AI System Overview

FIG. 1B illustrates and example decoy adversarial artificial intelligence (AI) system according to one embodiment. By way of example, the system generates an adversarial decoy pattern or signature intended to produce a false-positive detection of a target of interest. The decoy adversarial AI system also includes a pattern generator 140, an evaluation engine 145, an optimization reinforcement learning engine 150, and a deployer module 150. The function of these components may be the same as components of the stealth adversarial AI system described with FIG. 1B and further augmented to be configured specifically for a decoy mode as described herein.

In the decoy mode, the pattern generator 140 accepts an input specifying a target object type or signature that the user wishes to mimic as a fake object. For example, the object may correspond to the shape or outline of a tank or the thermal infrared profile of a human. The generative model produces one or more candidate decoy patterns or multi-modal signal configurations that are designed to cause an object detection model to output a high-confidence detection of the specified target type in a place or on an object where no such physical (or real world) target actually exists. For example, the system may generate an arrangement of visual shapes that an AI vision algorithm would interpret as a vehicle in imagery or generate a pattern of infrared light emission that mimics a human heat signature to an AI thermal camera.

The evaluation engine 145 evaluates each candidate decoy and the optimization reinforcement learning engine 150 optimizes in a similar iterative manner as in the stealth case, but with the objective inverted. That is, rather than minimizing detection, the decoy adversarial AI system is configured to maximize a confidence score (or frequency) of a detector to detect the chosen target, which is intended to be a false target. Through successive refinement, the decoy adversarial AI system produces an optimized decoy pattern or signal configuration that will induce the intended false perception.

The deployer module 155 receives the optimized pattern and formats it for deployment. The deployment may be, for example, as an image file or projector input to create a fake visual, a printing template to be applied to a dummy physical target object 160, or a specification of electronic signals (e.g. radar or IR emissions) to broadcast. When deployed in the field, for example, by applying the pattern to a physical decoy structure or by inserting the generated signal into live sensor feeds, the adversarial decoy causes AI systems to “see” a phantom object (e.g. a vehicle, person, or weapon) that isn't actually present. In effect, the same core technology can create illusory targets that distract or confuse an adversary's sensors, complementing the camouflage function.

In both modes (camouflage for stealth and decoy for deception), the system is designed for multi-modal operation and practical deployment constraints. A single adversarial pattern solution can be optimized to address multiple sensing modalities simultaneously. For example, a generated camouflage pattern might primarily alter an object's visible appearance but could also include features that shape a thermal infrared emission or radar waves reflection for an object differently, such that the object is concurrently harder to detect via thermal imaging and radar.

Deployment of decoy deployment may combine a printed visual pattern with an arrangement of heat emitters or radar reflectors so that the false target is perceived (or registered) across IR, radar, and other sensors just as a real target would. The system can ingest data about the expected deployment environment (terrain type, background clutter, typical sensor noise conditions, lighting, weather, etc.) and tailor the generated patterns or signals accordingly. This helps ensure that the output remains effective in context but appear plausible in the real world (e.g. blending with the environment for camouflage or matching realistic signatures for decoys). The final adversarial pattern or signature is typically provided in a deployment-ready format, for example, a digital texture file for printing onto a physical surface, or a device control data file for driving an electronic emitter. This enables ready implementation in field environments. This flexibility allows the same core system to be used both for physical-world applications as they may be applied as camouflage on vehicles, uniforms, or equipment. They also may be deployed as objects in an environment. Further, they may be deployed for digital or electronic deception, for example, by injecting decoy patterns into video feeds or sensor data streams, including augmented reality systems, or broadcasting fake signals in an electronic warfare context.

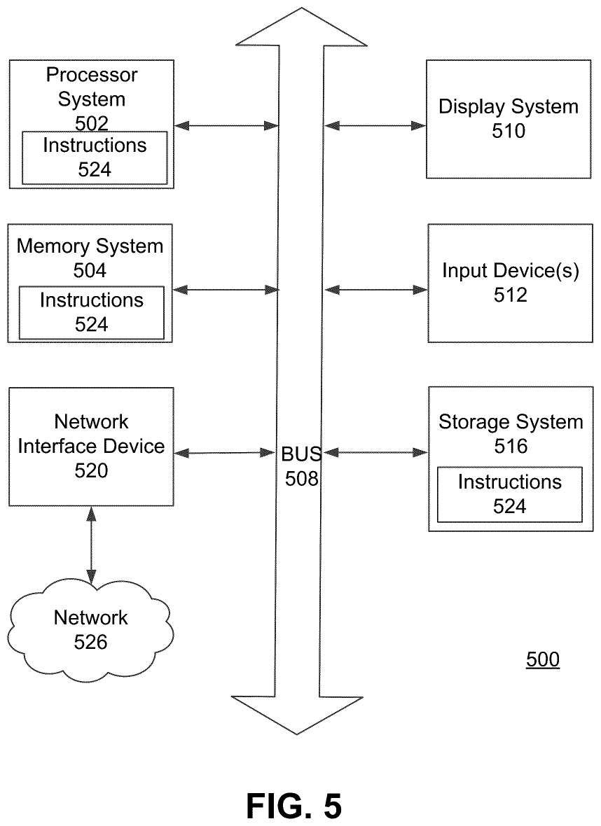

The system may be configured as software executing on computing hardware (ranging from high-performance servers to portable embedded processors), optionally paired with specialized hardware for deployment (such as display panels, three-dimension (3D) or industrial pattern printers (e.g., nylon or vinyl sheets or wraps), or electronic signal emitter devices. An example hardware (e.g., computing system) is described below with FIG. 5 and the system may use some or all of the components as shown and described. In various embodiments, the pattern-generation and evaluation engine can be hosted in a centralized server or cloud environment, or distributed across multiple nodes (for example, running on several vehicles or devices in the field). In some implementations, multiple fielded units each run a local instance of the system and periodically share performance data or model updates with a central repository or amongst each other, enabling a form of distributed learning or federated adaptation. In this way, improvements discovered in one deployment (e.g. encountering a new adversary sensor or developing an effective pattern tweak) can propagate to benefit all other units, creating a collective resilience against the adversary's evolving tactics. Additionally, the software/hardware system can be configured to securely communicate these updates to prevent adversary interception of pattern data. Overall, the invention provides an adaptive, intelligent adversarial countermeasure platform that significantly enhances stealth and deception capabilities against AI-based detection systems, while being mindful of real-world constraints and evolving threats.

The disclosed configuration provides for a smarter camouflage approach that can generate natural-looking, robust adversarial patterns against a range of detectors and that can evolve over time as conditions or adversary capabilities change. Conventional adversarial camouflage methods are static and narrowly optimized. A pattern that is printed or painted onto an object may lose effectiveness if viewing conditions change (e.g. different angles, distances, or lighting) or if the adversary updates or retrains their detection algorithms. Other conventional configurations only apply a particular fixed background or focus on a single type of sensor or model and do not account for multi-modal detection scenarios. In a modern multi-sensor surveillance suite, an asset that visually blends into the background might still be revealed by other signatures, for example, an infrared camera can spot the thermal emissions of an object at night, a LiDAR scanner can detect its shape via active depth sensing, or a radar system can bounce signals off it to detect its presence. Thus, a purely visual camouflage may fail if a thermal, acoustic, or radar signature of an object remains conspicuous. Camouflage systems such as electronic display fabrics or e-ink coverings that mimic the immediate background aim only at visual blending and lack the intelligence to counter AI-based recognition. They only copy whatever scenery is behind the object onto its surface, which might not confuse a sophisticated AI detector looking for telltale shape or texture features.

The disclosed configuration combines adversarial camouflage (hiding the real) and adversarial decoys (simulating the fake) in a single adaptive framework operable across diverse sensors. Beyond concealment of true objects, deception has long been a strategy in warfare and security, for example, using decoys to mislead the enemy. Historical examples range from inflatable dummy tanks and aircraft used in WWII to simple radar reflectors or heat sources intended to create phantom signals on sensors. Traditional decoys, however, are often crude and limited to mimicking one aspect of a target (e.g. just a visual likeness or a single radar blip) and may be easily identified as fake or be impractical to deploy at scale. With the rise of AI-driven multi-sensor surveillance, there is a parallel need for adversarial decoy systems that generate convincing false targets for machine perception. Such a system would produce patterns, signals, or combinations thereof that cause an AI-based object detector to confidently report an object that is not truly there. For example, an intelligent decoy might be a strategically placed arrangement that an AI vision model interprets as a human or vehicle when none exists, or an electronic emitter broadcasting a spoofed thermal or radar signature of a target. These AI-optimized decoys could overload an adversary's tracking systems with numerous bogus detections or divert attention away from real assets, thereby confounding targeting and surveillance efforts. However, much like camouflage, prior decoy techniques have been siloed and simplistic, often focusing on a single sensor domain or using predetermined templates.

Accordingly, the disclosed configuration beneficially combines adversarial camouflage (hiding the real) and adversarial decoys (simulating the fake) in a single adaptive framework operable across diverse sensors. The system that can algorithmically minimize an object's visibility or, conversely, maximize it (even creating fictitious targets), as required. The system produces robust, multispectral camouflage to conceal real objects and also generate deceptive patterns/signals to create illusory objects, in order to defeat or misdirect AI-based detection systems. The system provides a comprehensive, unified framework for adaptive adversarial pattern and signal generation encompassing both stealth and decoy applications.

### System Architecture and Shared Adversarial Pipeline

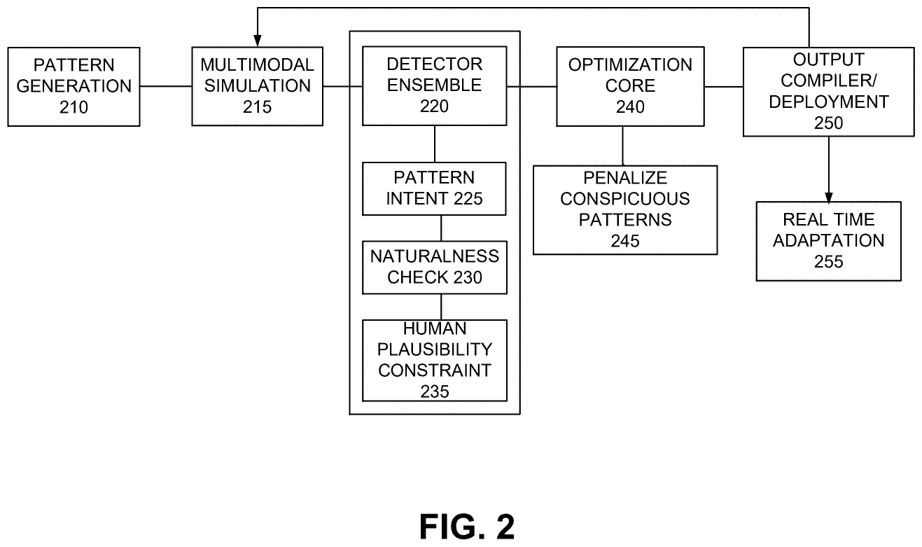

The adaptive adversarial pattern generation system (sometimes referred to simply as “the system”) may be conceptually divided into several functional modules or stages that work together in a closed-loop process to produce optimized stealth or decoy patterns. Referring now to FIG. 2, is a schematic block diagram of an example adaptive adversarial pattern generation system architecture according to one embodiment. The architecture may be deployed as software (e.g., application level or firmware) structured to enable a processing system (e.g., a processor system or computer system) to function as described herein. The components described in FIGS. 1A and 1B may be further augmented by the components described in FIG. 2.

In one embodiment, the system includes a pattern generator 210 (which may include input processing), a multi-modal scene simulation engine 215 (or multi-modal simulation engine) (e.g., a digital twin environment), a detector ensemble 220, an optimization core 240, an output compiler and deployment module 250, an optional real-time adaptation module 255, and a feedback module 260. The system also includes a pattern intent module 220, a naturalness check mode module 230, and a human plausibility constraint module 235, which may be optional. The system also may include a penalize conspicuous patterns module 245.

The pattern generator 210 communicatively couples with a multi-modal scene simulation engine 215. The multi-modal scene simulation engine 215 communicatively couples with the detector ensemble 220. The detector ensemble 220 communicatively couples with the optimization core 240 and the pattern intent module 225. The pattern intent module 225 communicatively couples with the naturalness check mode module 230. The naturalness check mode module 230 communicatively couples with the human plausibility constraint module 235.

The optimization core 240 communicatively couples with the output compiler and deployment module 250 and the penalize conspicuous patterns module 245. The output compiler and deployment module 250 communicatively couples with the optional real-time adaptation module 255 and the feedback module 260. The feedback module 260 communicatively couples with the multi-modal scene simulation engine 215.

The system configuration as illustrated is provided for illustrative clarity. System may be deployed in a configuration that may combine or distribute functions in various ways. For instance, some functions may be performed by the same software component, or certain modules might reside on cloud servers while others run on local hardware at the deployment site. The system is algorithm-agnostic to an extent, meaning that improved algorithms or models can be incorporated into these modules over time without departing from the scope of the invention (for example, the specific type of generative model or optimization technique can be updated as AI technology advances). In some implementations, an adversarial pattern may even be generated in a single pass by a trained model given the inputs, achieving a similar optimized result without an explicit iterative loop, whereas other implementations use iterative refinement as described below. The functional modules and stages are further described herein, including with example applications and deployment scenarios:

### Example Operational Flow of System Pipeline

In one example embodiment, the process may begin with the pattern generation module 210 providing input processing and context specification. The pattern generation module 210 may be configured to begin with an input processing stage that accepts various input parameters defining the objectives and constraints for adversarial pattern generation. The inputs typically include, target object or target class, objective mode (or pattern intent), environment context, sensor and threat profile, deployment and constraint preferences, and optional optimization criteria.

The target object (or target class) may include data identifying what real object is to be protected (in stealth mode) or what target signature is to be mimicked (in decoy mode). This could be, for example, a digital model or images of a specific vehicle, person, or piece of equipment to be camouflaged. Conversely, for a decoy, the input might specify a target type or profile that the decoy should resemble (e.g., “tank”, “soldier”, or a particular model of aircraft). The system may ingest a 3D model of the target object or reference imagery, or simply a category label (for instance, “pickup truck” as a class to mimic). If no detailed 3D model is provided for a target class, the system can retrieve or generate a generic model representative of that class to use in simulation.

The objective mode (or pattern intent) may include one or more parameters indicating the goal or intent of the adversarial pattern—e.g., stealth (to minimize detectability of the real target) or decoy (to create a false detectable target). This may be an explicit mode flag or inferred from the context (for example, an input might specify “cause detectors to not detect object X” for stealth or “cause detectors to report a false detection of object Y” for a decoy). The objective influences downstream evaluation: in stealth mode the system will treat lower detectability as success, whereas in decoy mode increased (false) detectability is the goal.

The environmental context may include information about the operational environment in which the adversarial pattern or signal will be deployed. This can include the background scenery or terrain type (forest, urban, desert, ocean, etc.), typical colors, textures, and patterns present in that environment, lighting conditions (day or night, spectral characteristics of illumination), and weather conditions. Environmental context helps ensure that a camouflage pattern blends in naturally or that a decoy signature is plausible in that setting. The user might input an environment profile, or the system might gather data from external sources (e.g., satellite images of the area, sample sensor readings, or a library of environment textures) to inform pattern design. For digital deception use-cases, the “environment” could pertain to properties of the sensor data stream itself (for example, video resolution, compression artifacts, noise levels), which define the context in which a digital adversarial insertion must appear natural.

The sensor and threat profile may include specifications of the sensing modalities and associated AI detection models that the adversary (or conversely, a friendly platform to be assisted) is expected to use. This profile may include a list of sensor types to counter or exploit: visible-light cameras, thermal infrared cameras, low-light night vision sensors, LiDAR, radar, acoustic sensors (microphones or sonar), and so on. It can also include details about known detection algorithms or classifiers (for example, if the adversary is known to use a particular neural network model or a certain object detection software). If exact models are not known, the system can use representative or state-of-the-art models for each modality as proxies. This sensor/threat profile configures the detector ensemble used in the simulation and evaluation steps (described below). For instance, a user might indicate that the adversary employs AI-enabled drones with infrared cameras and a vision-based person detector trained on a certain dataset; the system would then include similar IR and visual detection models in its ensemble to simulate that threat.

The deployment constraints and preferences may include practical constraints or user preferences affecting the generated pattern or signal. These may include physical constraints such as the surface area or shape available for applying a pattern, allowable colors or materials (e.g., due to safety, regulatory, or branding considerations), or restrictions like “do not cover or alter these specific parts of the object.” In decoy scenarios, constraints might detail what resources are available for constructing the decoy (for example, an input might indicate that an inflatable decoy shell of a certain size is available and that an IR heating device of a certain power can be used as part of the decoy, or that the decoy must be deployable by one person within a few minutes). Preferences could also include whether subtlety to human observers is critical (in stealth mode it usually is, whereas in some decoy cases human observers might not be present or the decoy might only need to fool machines), or whether the pattern should be reusable versus one-time-use. These inputs manage optimization to not produce solutions that, while effective against detectors, are impractical or undesirable to actually deploy.

The optimization criteria may include specific metrics or weighting factors for the optimization. By default, the system may evaluate the machine detection probability (to evade or to induce) as the primary metric, with a secondary consideration for human observability (minimizing conspicuousness for stealth or at least maintaining plausibility for decoy). However, an operator could adjust these criteria, for example, weighting invisibility to thermal sensors more heavily than to visual cameras if a mission deems IR stealth paramount or requiring that a decoy achieve a certain minimum confidence score on at least one modality.

Once these inputs are provided, the system performs any necessary preprocessing. This may include normalizing and formatting the input data, initializing internal data structures, and selecting appropriate internal models for the given scenario. For example, if no precise 3D model of the target object is provided for a camouflage task, the system can generate a proxy model (procedurally or from a shape library) to use in simulation. If the user only specifies a target class for a decoy (say, “tank”), the system can load a generic tank model along with typical signature data for that target type to serve as a basis for decoy generation. In this manner, the input module ensures that all subsequent stages have the required context to proceed.

In some embodiments, the inputs and/or constraints as described may be processed as a vector value and may be stored as an adversarial pattern using that vector value in a database. The vector value may be a multi-dimensional vector. The adversarial pattern stored as a vector value that may be used to define a candidate adversarial pattern in the process described herein. The selection of a candidate vector for production may be based on a vector value corresponding to the defined vector. The vector value may be used for comparison against other vector values to identify a closest fit to a desired pattern. As further described below, vector value may be adjusted based on a feedback process as described below where the inputs and constraints may be updated based on weighting factors. That updated vector value may be used to compare against previously stored vector values when selecting updated patterns based on the feedback loop described below.

After the pattern generation module 210 processes the input stage, the system enters a simulation stage in the multi-modal scene simulation engine 215 (or digital twin rendering module). The multi-modal scene simulation engine 215 is configured to generate a digital twin of the target object and its environment is created to evaluate candidate patterns under realistic conditions. Each candidate adversarial pattern or signal configuration generated by the system (see the later stage on generation/optimization) is applied in this virtual scene to test its effectiveness before any real-world deployment.

For a visual camouflage pattern, the multi-modal scene simulation engine 215 maps the pattern texture onto the 3D model of the target object (for instance, wrapping the 2D pattern image around the surfaces of a vehicle or person model identified in the image). The model of the patterned object is then placed into a simulated environment that reflects the anticipated real deployment context. For example, if a vehicle is to be camouflaged for a forest environment, the virtual scene might include a digital terrain with trees and foliage, and the vehicle model with the candidate pattern is rendered in that scene. In another example, if a person is camouflaged in an urban environment, the simulation might place a human model wearing the patterned attire against various city backdrops. Appropriate lighting conditions are applied that are consistent with the scenario (daylight, dusk, nighttime with infrared illumination, etc.), and the simulation may generate multiple viewpoints (different camera angles, distances, and vantage points) to ensure the pattern's effectiveness is robust from various perspectives.

For non-visual sensing modalities, the system similarly simulates a sensor signature for an object in those domains, using physics-based modeling or sensor-specific rendering techniques. For example, if infrared (thermal) simulation is applied, the system may simulate the heat emission profile of the object. If the object is a vehicle, the simulation might incorporate expected engine heat, exhaust heat, and ambient temperature effects. A candidate adversarial design for stealth might include not just a visual paint pattern but also specifications for thermal masking or insulation (such as areas where IR-blocking material or active cooling is applied). The multi-modal scene simulation engine 215 adjusts the thermal image of the scene accordingly to reflect how the pattern (and any thermal measures) alters the heat signature. Conversely, for a decoy, the simulation can include added heat sources in the scene to mimic a target's thermal output (for instance, simulating warm regions corresponding to an engine or human body if the candidate decoy pattern includes heaters).

In another example, if radar simulation is applied by the multi-modal scene simulation engine 215, the system uses a radar cross-section (RCS) model of the object and modifies it based on adversarial pattern elements. For stealth, this could involve simulating the effect of radar-absorbing material (RAM) coatings or geometrical alterations (e.g., reflective patches arranged to scatter radar waves away from the receiver) included in a pattern design. The simulation may computationally emit radar pulses at the scene and compute the return signal or simply evaluate qualitatively whether the pattern's proposed modifications would reduce the radar detectability. For decoy patterns, the simulation can include added radar reflectors or resonant structures defined by the pattern to simulate a stronger radar return corresponding to a false target.

If LiDAR simulation is applied by the multi-modal scene simulation engine 215, the system simulates the point cloud or depth map that a LiDAR sensor would produce for the scene. If an adversarial pattern involves 3D modifications to the object's surface (for example, adding protrusions, skirts, or altering its shape outline), these changes are reflected in the simulated LiDAR return. In stealth mode, pattern-induced shape modifications might aim to break up the recognizable geometry of the object. In decoy mode, an arrangement might be simulated that yields a point cloud resembling the desired fake object (for example, producing a cluster of points shaped like a tank turret where there is none).

If acoustic or other sensor simulation is applied by the multi-modal scene simulation engine 215, the system can also simulate acoustic signatures (noise profiles) or other sensor outputs as needed. For instance, for an acoustic sensor, the simulation might adjust the sound profile of the scene if the adversarial design includes measures to dampen noise (stealth) or generate decoy noises. For a sonar or underwater scenario, it could simulate how an object's sonar reflection or emission is altered by an adversarial coating or signal.

The multi-modal scene simulation engine 215 employs known physics models and sensor models to render how the object with a given adversarial pattern would appear to each type of sensor in the threat profile. The result is a set of synthetic sensor data streams (e.g., rendered images, heat maps, LiDAR point clouds, radar returns, audio waveforms, etc.) that show the predicted outcome of using the candidate pattern in that scenario. This provides a controlled virtual experiment to gauge each pattern's effectiveness.

The simulation stage allows rapid and safe evaluation of many candidate patterns without needing to physically manufacture or test each one. It approximates the adversary's perspective of the scene. In some embodiments, this module leverages game engine technology or specialized rendering software to produce high-fidelity, real-time sensor outputs. It may also incorporate random perturbations and noise to make the evaluation robust-for example, adding sensor noise, slightly varying the environmental conditions or object's pose, or other variability between simulation runs. By doing so, the system can test how robust each candidate pattern is to change and ensure it's not overfitting to one exact scenario.

Communicatively coupled with the multi-modal scene simulation engine 215 is the detector ensemble module 220. The detector ensemble module 220 contains a suite of object detection models corresponding to the adversary's (or target platform's) perception capabilities. As used herein, a “detector ensemble” refers to a collection of multiple detection algorithms and/or machine learning models, potentially spanning multiple sensor modalities, that the system uses to evaluate whether a target object would be detected or not. This ensemble might include, for example, one or more state-of-the-art image recognition neural networks for visible-spectrum input, trained to recognize the class of object in question (e.g., person, vehicle), an infrared (thermal) object detector or anomaly detector for simulated heat images, a LiDAR-based object detection or classification model for point cloud data, a radar signal processing algorithm or classifier for radar returns if applicable, or any other AI models relevant to the expected observers, such as acoustic event detection models (to “hear” a drone or vehicle) or sensor fusion algorithms that combine inputs (for example, an AI that analyzes combined visual and IR feeds).

The detector ensemble module 220 includes a pattern intent module 225. The pattern intent module 225, for each model in the ensemble, processes the simulated sensor data of the scene that includes the target object with its candidate pattern. In essence, the system is posing the question of “If this pattern were deployed, would the adversary's detector notice the object (or falsely think something is there)?” Under normal conditions (no adversarial pattern), these detector models would correctly detect the object in the simulation. The adversarial pattern's purpose is to cause these models to fail in detection (for stealth) or to produce a detection where there should be none (for decoy).

The detector ensemble 220 also includes the naturalness check module 230. During evaluation, the naturalness check module 230 of the system records the outputs of all detectors in the ensemble. These outputs could be binary decisions (detected vs. not detected), confidence scores (likelihood of target presence), class labels (e.g., the model might misclassify a camouflaged vehicle as “background” or as a different benign object), or more detailed data like bounding boxes and segmentation masks indicating where the model thinks an object is. For example, for a candidate camouflage pattern, a vision model in the ensemble might output “no person detected” or misidentify the person as part of the foliage; a thermal model might output a very low confidence that a human is present because the heat signature was disrupted; a LiDAR classifier might fail to recognize the shape of the vehicle. In decoy mode, success would manifest as the detectors outputting high-confidence false positives—e.g., the AI reports “tank detected at coordinates X” in an image where, in reality, there is only a patterned canvas or device placed as a decoy.

There are various ways to compute this metric. For example, in one embodiment, for stealth objectives the system could define a composite stealth score that penalizes any detection by any model in the ensemble. For instance, the worst-case detector confidence (the highest confidence among all ensemble models that the target is present) might be taken as the score in which lower is better, and a perfect pattern would yield very low confidence across all models. Alternatively, a weighted sum of confidence scores could be used if certain sensors are more critical than others. For decoy objectives, the metric could be the positive detection confidence for the fake target class, for example, taking the maximum or an average across relevant models. For example, if the decoy is meant to simulate a tank, and three different models (visual, IR, radar) all report detections of a tank with various confidence levels, the metric might be a weighted sum or simply the highest confidence, where higher is better. The metric can also incorporate secondary penalties or bonuses, such as a penalty for patterns that are too obvious to humans, which may tie into constraints discussed herein.

Optionally, as part of the evaluation stage, the plausibility constraint module 235 of the system performs a human observability or plausibility check on each candidate's appearance (primarily for stealth mode, but also applicable to decoys if human observers might encounter them). This can be implemented as a separate module or integrated into the fitness metric. The idea is to ensure that the pattern not only deceives machines but also remains inconspicuous to human eyes. The system may use predefined heuristics and filters (for example, flagging patterns that have extremely high contrast, unnatural colors, or repetitive digital artifacts that a human would notice), or employ a trained model to predict human detectability (e.g., a neural network that has learned to classify images as “natural” or “suspicious”). Images of the target with the candidate pattern can be analyzed by this human-vision model or compared against a library of natural textures. If a candidate pattern achieves excellent machine evasion by introducing obviously bizarre visuals (like bright random noise), that pattern would either be filtered out or heavily penalized in the scoring. Similarly, for a decoy, if the scenario is such that humans might directly see the decoy, the system can ensure that the decoy's appearance is reasonably convincing to a casual human observer (at least under the conditions expected, such as at distance or in low light). The inclusion of this plausibility constraint ensures that the optimized pattern is not only algorithmically effective but also practical in the real world.

By the end of this evaluation stage, every candidate pattern has an associated performance score (or set of scores) indicating how it fared against the simulated detectors (and any other criteria like human plausibility). These scores are then used to guide the next stage of the process, which is the automatic improvement of the patterns.

Referring next to the optimization core module 240 (adversarial pattern generator and refinement loop), it automatically searches for an optimal pattern or signal configuration by iteratively improving candidates based on the field feedback 260 that was output from the optimization core 240 and output compiler/deployment 250 and processed through the multi-modal simulation and the detector ensemble 220. In effect, this module is “training” the camouflage or decoy pattern in a loop of trial and feedback, treating the detector ensemble as an adversary to beat. The invention is not limited to a single optimization algorithm; any suitable method of iteratively adjusting the pattern using the detector feedback is encompassed. Some exemplary techniques include:

Also in the optimization core module 240, the system is configured to execute evolutionary algorithms (genetic algorithms). These algorithms allow each candidate pattern as an individual in a population. After each round of simulation and evaluation, candidates are assigned fitness scores as described. The optimization core then selects the fittest candidates (those with the best stealth or decoy performance) and uses them to produce a new generation of candidate patterns. This can involve recombining elements of two or more successful patterns (crossover) and randomly perturbing or altering parts of patterns (mutation). For example, two effective camouflage textures might be blended together to see if their combination yields an even better pattern, or small random changes might be applied to a top-performing pattern to explore nearby design variations. Over successive generations, this evolutionary process tends to improve the population's performance, as ineffective designs are discarded and effective traits propagate. The loop continues until a stopping criterion is met (such as reaching a pattern that meets the desired performance threshold or exhausting a set number of generations with no further improvement).

In another approach, the optimization core module 240 is configured to apply reinforcement learning (RL). For example, pattern generation can be framed as a sequential decision-making problem where an agent incrementally constructs or modifies a pattern and receives feedback (a reward) based on the adversarial performance. For instance, an RL agent (which could be implemented as a neural network policy) might “paint” a pattern stroke by stroke on a virtual canvas covering the object. After each full pattern is applied and evaluated, the agent gets a reward score (high reward for good stealth or decoy outcomes). Using techniques such as policy gradients or Q-learning, the agent updates its strategy to favor actions that lead to higher rewards. Over many episodes of trial and error, the agent learns to assemble patterns that fool the detectors. This approach is useful if the search space (all possible patterns) is extremely large, as the agent can learn heuristics for constructing effective patterns rather than random search.

If the detector models are differentiable (which is often the case for neural networks) and the simulation can be made differentiable or approximated as such, the optimization core module 240 of the system may apply gradient-based optimization using gradient-based techniques inspired by digital adversarial example generation. In this scenario, the pipeline from pattern to detector output is treated like a differentiable function. The system computes the gradient of a loss function (e.g., the detector's confidence in the target's presence) with respect to the pattern parameters (for example, the pixel values of the texture). This gradient indicates how to change the pattern to reduce detectability (for stealth) or increase detectability (for decoy). The system then adjusts the pattern in the opposite direction of the gradient (for stealth, to decrease the detection score) or along the gradient (for decoy, to increase the detection score), using iterative steps like gradient descent/ascent. Constraints or regularization are applied here to ensure that the pattern modifications remain within physically realizable bounds (for instance, staying within the range of printable colors or textures, and not introducing features that cannot be implemented on the actual object). This method can quickly converge on an effective solution, although it requires careful handling of constraints so that the optimized pattern is not just effective in theory but also deployable in practice.

In some cases, especially for specific modalities or simpler pattern parameterizations, the optimization core module 240 may apply heuristic or combinatorial search. For example, if the adversarial pattern is defined by a combination of discrete components (like placing a set of radar reflector devices on a decoy), the system might perform a search over possible configurations (perhaps using greedy search or simulated annealing) rather than gradient or evolutionary methods.

Often, the optimization core module 240 of the system may employ a hybrid of these approaches. For instance, the process might start with a generative model (like a GAN) proposing an initial diverse set of patterns that are already reasonably effective (biased towards plausible designs) and thereafter switch to an evolutionary refinement on that population. Or an RL agent might be used to fine-tune a pattern that was roughly optimized by a gradient method, to introduce some non-intuitive variations that gradients might miss.

During each iteration of the field feedback loop 260, the sequence may have the pattern generator 210 produce one or more new candidate patterns, either from scratch or by modifying previous candidates. The modification may be based on what parameters that may need to be adjusted for the pattern to be closer to being a candidate pattern. These candidates are passed into the simulation module 215 and evaluated by the detector ensemble 220, yielding performance metrics. The optimization core module 240 uses the feedback to determine how to generate or select candidates for the next iteration. This may include, for example, updating weights in a neural generator (if using gradient descent or adversarial training), selecting parents for breeding a new generation (in evolutionary algorithms), updating an RL policy with new experience, or the like. The feedback loop repeats with the new candidates.

This adaptive loop continues until an optimized adversarial pattern (or set of patterns) is found that meets the predefined success criteria. The stopping condition might be, for example, that the target object's detectability (as measured by the ensemble) falls below a certain threshold (stealth success), or that the false target detection confidence exceeds a threshold (decoy success). It could also be a plateau in improvement or a resource cap (like a maximum number of iterations or time).

Through this process, the system effectively learns an adversarial solution against the specified detectors. The result is often a pattern design that is counter-intuitive or highly complex and that leverages subtle perturbations and cross-modal interactions that a human designer likely would not conceive. The multi-objective, multi-modal nature of the optimization ensures that the final pattern does not just exploit one sensor while neglecting others but rather addresses the full set of sensors in the threat profile. For example, the system will not settle for a solution that fools the camera but leaves an obvious thermal signature; it will keep adjusting until the thermal detectability is also reduced (or an acceptable trade-off is reached). The outcome is an integrated adversarial design that considers the entire spectrum of detection methods simultaneously.

Additionally, the optimization process can incorporate randomness and diversity to avoid overly concentrating on a single optimum that might be brittle. In some embodiments, instead of converging to one “perfect” pattern, the system may output a handful of top-performing patterns or a parameterized family of patterns. This ensures that the adversary cannot easily learn one specific pattern if it were repeatedly used. In practice, the system could even be set to introduce slight variations each time it deploys a pattern (staying within the effective family), creating a moving target so that the adversary's models have difficulty learning to recognize the trick.

Referring next to the output compiler 250 (formatting/deployment preparation), once an optimized adversarial pattern or signal configuration is obtained from the optimization core module 240, the system prepares the result for real-world deployment. The output compiler 250 takes the digital description of the optimized pattern and converts it into a usable form for end-users or deployment hardware. The combination of the finalized pattern data and its deployment instructions may be viewed as a deployment bundle ready for implementation.

For adversarial visual patterns (camouflage prints, decals, or painted graphics), the output may be one or more image files or texture maps that correspond to the pattern to be applied. The output compiler can process these images into the appropriate format and layout for the intended application method:—It may tile or panelize the pattern if the surface area to cover is larger than what a single sheet or printer can handle, ensuring that pieces can be assembled seamlessly.—It can generate geometry-aware templates. For example, if the target object has a complex 3D shape, the compiler can produce a flattened UV mapping or stenciling guide that shows how the 2D pattern wraps onto the 3D surfaces. This might involve segmenting the pattern into labeled sections (e.g., Panel A for the left side of a vehicle, Panel B for the top, etc.) with instructions on alignment.—The module might also produce augmented reality (AR) markers, QR codes, or other registration aids that, when viewed through an AR device or a dedicated app, help technicians align and apply the pattern correctly on the object. If the pattern will be displayed on an electronic ink or display surface on the object (rather than physically painted), the output might be a digital file to be loaded into that display system.

For adversarial emissive signals or multi-modal decoy outputs, the output compiler 250 produces the device control data or configuration instructions needed to realize the pattern's effects. For example, if the solution involves thermal emission (heating or cooling certain spots), the output could include a control script or firmware for the thermal emitter hardware, specifying when and where to produce heat to mimic a target's IR signature. In another example, if radar reflection has been optimized via deployable corner reflectors or antennas, the output might include specifications for placing those reflectors, or if using an active radar transmitter, the waveform parameters (frequency, modulation, pulse timing) that it should broadcast to spoof a radar. Also, for example, for acoustic decoys, the output could be an audio file or a program for a sound generator that produces the necessary engine noise or footsteps pattern at the right intervals and volumes. Essentially, the compiler translates the abstract “pattern” (which might in this context be a sequence of signals or an arrangement of hardware) into low-level instructions or data that can be fed into the relevant deployment devices (printers, projectors, LED panels, IR lamps, speakers, radio transmitters, etc.).

If the adversarial solution includes physical 3D components or structural modifications (for example, a certain shape of shroud, decoy structure, or a rig for emitters), the output module can generate CAD files or 3D printing models for those components. For example, the system might determine that adding a particular 3D foam attachment to the top of a helmet helps break its recognizable shape in LiDAR; the output would then include the design for that attachment, so it can be manufactured. In decoy cases, if a dummy object needs a specific form factor, the output might include diagrams on how to construct or arrange the decoy apparatus (where to place emitters on an inflatable tank, etc.).

In addition to the pattern and hardware instructions, the output compiler 250 may generate human-readable documentation or instructions to accompany the deployment bundle. This may include a step-by-step guide for technicians or users on how to apply the camouflage pattern or set up the decoy device. For example, instructions on surface preparation, printing settings, application of adhesive films, or assembly of decoy components.—A list of recommended materials and tools (specific paint color codes, fabric types, adhesive qualities, printer models or settings, electronics specifications) to achieve the intended results, ensuring that the realized pattern matches the optimized design. The output compiler 250 also may generate and output safety notes or operational guidelines. For example, if a decoy includes an IR heater, instructions might caution not to operate it longer than a certain duration or within certain conditions. If a camouflage pattern is environment-specific, notes might mention that its effectiveness could diminish if used in a very different environment than intended. The output compiler 250 also may generate and output a maintenance or lifespan information, such as how long a printed pattern might last outdoors before needing replacement, or how to recalibrate an electronic decoy device.

The output compiler 250 bridges the gap between the digital optimized design and the real-world adaptation 255, ensuring that the end users can confidently deploy the adversarial pattern and achieve the expected effect. It accounts for practical considerations like the shape of the object (providing distortion corrections so that once a flat pattern is applied to a curved surface, it appears as designed), the scale (outputting files at the correct physical dimensions), and integration (like marks for where to plug in modular emitters or how to orient a decoy relative to the expected viewpoint of the adversary).

In some embodiments, especially in highly automated deployment scenarios, the output compiler 250 may directly interface with manufacturing or application systems. For example, the system might send the pattern file directly to a large-format printer or to a robotic painting drone that will apply the pattern onto a vehicle. In a decoy network, the system could transmit the signal configuration to a remote decoy device over a network, causing that device to start broadcasting the fake signature immediately. In such cases, the “deployment bundle” may be delivered electronically to the field unit, which then executes the instructions to realize the adversarial pattern. This also enables an adversary camouflage/decoy as a service (A/CaS), in which a central server may generate optimized patterns and pushes them to client devices on demand.

Finally, the system may record each optimized pattern and its context in a secure database or library, along with metadata about its performance. This archive assists with future operations—if a similar scenario arises, the system can retrieve a proven pattern as a starting point or reuse it outright if appropriate.

In some embodiments, the system includes an optional real-time adaptation and feedback mechanism 260 that allows the adversarial pattern to evolve even after deployment. The nature of adversarial engagements is that the “target” (the adversary's detection systems) may change over time-for example, the adversary might update their algorithms or deploy new sensors in response to discovering a countermeasure. The invention anticipates this by enabling continuous learning.

In some example embodiments, a deployed system (e.g., a vehicle equipped with a dynamic camouflage display or a decoy drone in the field) continues to run the core optimization loop (or a lightweight version of it) on the edge device itself. The system can periodically take new readings from its environment and from any friendly sensors (to assess if it is being detected) and adjust the pattern on the fly. For instance, consider a vehicle that has an electronic ink exterior for camouflage: as it moves from a forest into an open field or as lighting shifts, the on-board system can gradually update the displayed pattern to maintain optimal stealth against current conditions. If an enemy sensor starts pinging the vehicle (detected via some electronic warfare sensor), the system might react by switching to a pattern that is known to be more effective against radar, etc.

If full real-time re-computation is too slow, the system may be configured to maintain a library of pre-optimized patterns for different conditions and quickly switch between them based on triggers. For example, it might have a set of patterns indexed by environment type or threat level and choose the best one for the moment, possibly with minor tweaks.

Continuous learning is facilitated by deploying feedback data. If a camouflaged asset is partially detected (say an enemy AI managed to catch it on thermal but not visual), those events can be recorded and sent back to a central server or used locally to adjust the model. The system can then re-optimize or fine-tune the pattern to close that gap. Likewise, if a decoy stops fooling the enemy (perhaps the enemy updated their system to ignore the specific signature the decoy was using), the system can be alerted (either by observing that the decoy is no longer being targeted or via direct communication) and respond by generating a new variation of the decoy pattern that regains effectiveness.

When multiple units in the field employ the system, they can optionally share telemetry and lessons learned. For instance, a network of drones each running this adversarial pattern software could send back data on which patterns worked or failed in their encounters, and a central or peer-to-peer update mechanism can incorporate these findings into the detector ensemble or generative models. In effect, the more the system is used, the smarter and more robust it becomes, continually outpacing the adversary's adaptations. Secure communication protocols are used for these updates to prevent an adversary from intercepting or tampering with the pattern data being shared.

Through ongoing adaptation, the disclosed configuration provides not just a one-time static pattern, but a capability but also a moving-target defense (or offense, in the case of decoys) where the countermeasure is always adjusting itself. Stealth and deception measures produced by this system need not be static products but can function as an evolving service that stays one step ahead of evolving threats.

### Stealth Camouflage Mode Embodiments (Wraith Mode)

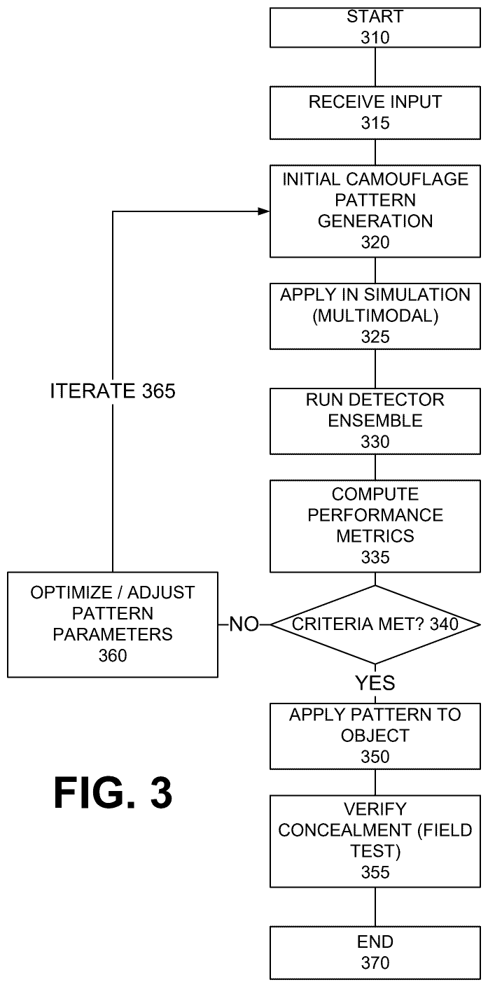

Turning now to FIG. 3, it illustrates a flowchart of an example process for generating and deploying an adversarial camouflage pattern (stealth mode) for concealing a real object from machine vision detectors according to one embodiment. In a stealth or camouflage application (sometimes referred to by the codename “Wraith mode”), the system is configured to minimize the detectability of a real target object across one or more sensing modalities.

A pipeline with stealth-focus starts 310 with input acquisition 315. The input may be, for example, a target, environment, or a sensor profile. The process generates 320 an initial camouflage pattern. By way of example, the adversarial camouflage patterns generated for stealth are typically designed to blend the target object into its background and to break the object's recognizable features that detectors rely on. Because of the generative process, if the system is context-aware, it nay produces patterns that incorporate colors and textures sampled from the surrounding environment. For example, if the target object will operate in a wooded area, the generated pattern may include abstract leaf and branch shapes in the same green and brown palette present in the forest. Unlike conventional camouflage, however, these patterns are not merely copying the background—they are optimized specifically against AI detectors. This means the pattern might include subtle perturbations or noise that, to a human eye, just look like slightly mottled shadows or natural variance, but to a machine vision model, these perturbations interfere with the model's ability to recognize the object's outlines or texture.

The system is configured to provide for display a pattern that remains plausible to observers. As described earlier, a human-plausibility filter is applied during optimization to remove candidates that, for instance, have random high-frequency noise or clearly artificial elements. The resulting optimized camouflage often looks like a sophisticated, environment-matched paint job or textile print. In some cases, the pattern can mimic innocuous objects or backgrounds—e.g., making a military vehicle look like a civilian car to AI, or a soldier's silhouette on thermal appear like a random patch of cooler background. This is achieved through the ensemble feedback: if any detector is picking up the target, the pattern evolves further until those detections drop.

The process continues with applying 325, a simulation that may be multi-modal. Here, the process is configured so that the system may concurrently address multiple sensor modalities. Traditional camouflage might only address visible light, but here, the optimized solution might include a combination of measures. The process runs 330 (execute) detector ensemble. For example, for a visual detector it may be a printed or projected pattern on an object surface that confuses camera-based detectors. In another example, for a thermal detector of the system may apply a thermal solution such as IR masking materials (such as thermal blankets or cooling paints) in specific regions. The pattern output might specify that certain high-heat areas (engine compartments, exhausts) should be covered with additional insulation or actively cooled. The effect is that the object's thermal image is muted or altered to avoid the typical hot spots that algorithms may seek. In yet another example, for a radar detector the pattern might incorporate placement of radar-absorbing material (RAM) coatings in strategic patches or geometric addons like angular plates that deflect radar. The optimization process may determine that adding a thin RAM panel over a particularly reflective section of a vehicle dramatically lowers the radar return without affecting other aspects; such an addition would be included in the output instructions. Further by example, for a LiDAR detector the system might identify appendages or shape modifications that reduce the distinct 3D profile of the target as may be the case in LiDAR applications. For example, a rifle used by a sniper could have a lightweight frame that alters its characteristic straight-line shape in a LiDAR scan. The adversarial pattern could thus involve a kind of 3D “wrap” or attachment, not just coloration.

A unified treatment by the system balances cross-modal measures across purposes. It may seek an optimal balance for determining 340 whether particular threshold criteria are met. For example, slightly compromising in one modality if needed to dramatically reduce detectability in another, but always meeting the threshold requirements set by the threat profile input. If there is a determination that criteria are not met, the process may optimize (or adjust) 360 parameters that are fed back into the initial camouflage generation step 320 through an iteration 365 process. The detector ensemble may receive the parameters through the feedback iterations to, for example, generate a certain visually subtle pattern which causes a negligible increase in thermal visibility. The optimization process may decide if that trade-off is acceptable or if it should adjust to improve thermal at some expense to visual, depending on the weights given. That same process may be applied to other detector ensemble processes.

The process continues with computing 335 stealth metric. The stealth patterns produced are robust within the expected range of operational conditions. Because the simulation tests candidates under varying angles, distances, and lighting, the final pattern is not a one-angle trick. For example, the camouflage might include gradient shading that adapts an object's appearance under different sun angles to avoid casting telltale shadows that AI could notice. If the mission involves day-night cycles, the pattern might be a composite that has elements effective in daylight (color patterns) and other elements (thermal regulation) that kick in at night. In scenarios where the adversary might retrain their models, the system can be periodically re-run with updated detector models, producing updated patterns (which could be distributed as software updates to digital camouflage systems or as new printouts for physical recoating).

Once the threshold criteria are met 340, the process deploys 345 the optimized camouflage for the target. The optimized camouflage may be output to apply 350 onto a physical target. By way of example, to apply the optimized camouflage to the target, the deployment bundle will include everything needed as discussed. For example, if the pattern is meant to be physically printed on vinyl wraps and applied to a vehicle:—The bundle provides the print files for those vinyl wraps, already segmented and scaled. The process may specify the exact positions for each wrap panel on the vehicle. It also may include calibration markers, for example, small fiducial symbols in corners, to ensure precise alignment. If the pattern requires particular paint applications, it may list paint codes and a layout diagram for a painter to follow. If the deployment is electronic in which electronic displays may be used on a physical object (e.g., an active camouflage suit with e-ink panels that changes patterns on command), the bundle may include the digital images to display or even the program to cycle through patterns if dynamic adaptation is to occur. The system may conduct field tests using computing AI models to verify 355 that the object is adequately concealed. Feedback may be applied to update the c camouflage and retest until verification passes and the process ends 370.

In summary, the disclosed configuration with process described keeps beneficially keeps physical assets hidden from computer machine analysis that are seeking those physical assets. The intelligent, adaptive design of camouflage beneficially counters modern AI systems across multiple spectra, without tipping off human observers or the machine models. The end product may be a static camouflage pattern or a dynamic solution that can include specialized materials and devices to cover all detection bases.

### Decoy Generation Mode Embodiments (False-Target Deception)

In decoy or deception applications, the system (in what might be referenced as a “decoy mode”) is tasked with effectively manufacturing a phantom target. The manufactured phantom target is made so that something that is not actually a high-value target appears as one to adversarial sensors. This mode uses much of the same pipeline described earlier but with the opposite objective function. That is the process starts 410 and acquires 315 the inputs, which may be a signature specification for the target. By way of example, the input for decoy mode typically includes a description of the target that the user wants the adversary to falsely perceive. This could be very specific (e.g., make it look like this particular aircraft with tail number, shape, and all) or more general (e.g., “a human soldier” or “a tank”). If specifics are provided (like a 3D model of an enemy aircraft and its known sensor signatures), the system uses that as the blueprint for the decoy's intended signature. If only a general class is given, the system draws on stored data or models of a representative example of that class.

Based on the desired false target, the system generates 420 candidates of an initial decoy patterns or signal configurations that would produce sensor readings resembling the real target. For example, for visual decoys the goal may be to create a visual false target (for camera-based AI). Here, the system may generate a 2D pattern that, when flatly viewed, looks like the target object. For instance, a tarp or canvas could be printed with a perspective-corrected image of a tank such that from the sky it looks like a tank to drone cameras. More sophisticated, the pattern might not be a direct photo but an adversarial design that triggers the AI to think it sees the target (taking advantage of the AI's learned features). For example, bizarre as it sounds, a seemingly abstract arrangement of shapes on a wall might trigger a poorly trained AI to detect a person. The generative model, guided by the detector ensemble, finds these “trick” images.

The process also may simulate 425 multi-modal composite decoys and run 430 (or execute detector ensembles to compute 435 decoy metrics. Often the decoy will involve a combination of modalities for credibility. The system might propose, for example, an arrangement where a visual pattern is combined with an infrared heat source and a radar reflector. Individually, each modality's cue may not perfectly resemble a real object, but together, to a multi-sensor AI, they form a convincing target signature. One candidate decoy configuration may attach a triangular trihedral radar reflector of x size to a pole at y height (to mimic radar return of a vehicle's metal body), place an IR heating pad with a specific heat output at ground level (to mimic an engine's thermal spot), and print a flat image that looks like the top view of the vehicle on a sheet on the ground. This combination may fool an AI that fuses radar and IR and visual as it “sees” a radar target, a heat blob, and a visual outline consistent with a vehicle, and thus might report a vehicle with high confidence. The system may arrive at such combinations through the optimization loop, trying different mixes of pattern elements and checking if the ensemble of detectors all responds as if a real target is there.

For optimization 460, the system may try to cause detector confusion in the opposite direction of stealth, i.e., high detection confidence where there is actually nothing of value. Here, the system is computing 435 decoy metrics for false positives. The detector ensemble in this case is set to look for the target class in question, and the adversarial decoy fitness is high when the detectors are strongly convinced. The iterative loop 465 will enhance features of the decoy that contribute to detections. If during evaluation, the visual detector was almost convinced (say 80% confidence of a tank) but the thermal detector wasn't (maybe only 20% confidence), the optimization might tweak the decoy design to put more emphasis on thermal signature in the next iteration (e.g., upping the heat output or adjusting its distribution). Conversely, if the decoy is too obvious in one modality (perhaps the radar return is actually too strong or too perfect and a sophisticated AI flags it as unusual), the system might actually dial it down to be more realistic. This highlights that decoy patterns often try to identify an ideal mimicking reality and not just max values. Thus, the metric can include realism constraints (for example, do not exceed the typical radar cross-section of the real object by too much, as that could be a giveaway).

In many decoy scenarios (like battlefield deception), fooling human observers can be a secondary goal but often the primary aim is machine detectors. If humans are also a concern, the decoy can be made visually convincing (for example, painting the inflatable to look real, not just adversarial gibberish). If humans are not around (e.g., trying to fool an autonomous drone surveillance at night), the decoy pattern might ignore human-visual conspicuousness completely and use patterns that look odd in daylight, but a drone AI might see as a target in infrared. Overall, the system uses computed decoy metrics to determine how often false positives are detected and may be compared against a threshold to determine 440 whether a particular threshold is met. If not, the process may iterate 465 through a feedback loop back to the pattern generation 420 by optimizing 460 (or adjusting) pattern parameters.

Once the process determines 440 that the threshold criteria are met, the process continues with preparing 445 a deployment. Here, the output of decoy mode often includes instructions to create (or generate) a decoy apparatus. This may be a physical object such as a dummy or inflatable structure that provides a baseline shape. The adversarial pattern might then specify how to decorate this structure. For example, the surface of the decoy may be printed with a pattern (e.g., camouflage that matches what a real tank in the area would wear, combined with adversarial perturbations). Further, locations on the decoy where emitters should be placed (for heat, light, RF, etc.) are specified. For example, there may be output details on where to place an IR lamp inside a compartment area of a dummy tank engine to simulate engine heat or mount a corner reflector on the top to simulate the radar return of a turret. If no physical dummy hull is used but rather an electronically generated image, e.g., projecting a hologram or displayed image, the system may output digital visual projection parameters or the configuration for the devices to display through a medium, e.g., a set of drones holding a projection screen.

Because decoys might need to be set up quickly in the field, the output of the system may be mindful of deployment constraints. It may be configured so that simpler configurations are deployable. For example, rather than of a full-size inflatable plane which may take hours to inflate, it might opt for a smaller form factor with just key signature augmentations that sufficiently deploy the camouflage with features such as tall poles with reflectors and a camouflage net to fill in the visual that would pass field test verification 455 before ending 470.

Decoy embodiments may also consider how the false targets are meant to be used tactically. For example, for swarm decoys the system may generate patterns for multiple coordinated decoys. For instance, it might output slightly varied patterns for a dozen small drone units that will fly information. Each unit might carry an IR LED and a small radar reflector; when they fly together in a certain formation, the collective signal appears as a single larger moving object on sensors. The output instructions could include the flight formation pattern and timing (this is an example of emission orchestration, where multiple emitters are coordinated to form one illusion). For digital decoys, a decoy mode may be used in cybersecurity or sensor feed injection. For example, if an AI system is monitoring closed circuit television (CCTV) feeds, the output could be an image overlay or video clip to inject that causes the AI to register a person or object that isn't there. The system might output a small translucent sticker or digital watermark that, when placed on a camera lens or within a video stream, fools the vision model into seeing something (this technique is analogous to known adversarial patches, repurposed as decoys).

The system may be configured so that the process may output a defined kit of components. For example, a decoy kit for a vehicle might include a foldable frame, a printed fabric cover with the adversarial pattern, a heating element, and a corner reflector. The instructions would tell how to assemble these so that from all relevant sensors it looks like a real vehicle. Because the system's optimization considered all those sensors, the resulting kit is much more effective than a traditional decoy (which might only look good visually but have no IR signature, etc.).

Just like camouflage patterns, decoy patterns may be updated. If the adversary starts ignoring a particular decoy because a decoy has been identified as such, the system may generate a new variant. For example, maybe the enemy realized that all fake tanks have a certain identical heat pattern and learned to spot it; the operator can request a new decoy pattern with variations in heat signature placement, and the system will output a modified deployment bundle. The output bundle also may include additional instructions from machine learning models that received feedback on how the original decoy was identified and propose changes. For example, data collected during the original training process to generate the original output may be augmented from date in the field that may suggest how the decoy was detected. This data may be fed back into the system for the optimization 460 process for further iteration. It also may be determined that the parameters were correct but external environmental conditions of the deployment may have been the issue and may advise accordingly. For example, it may suggest moving the heater to a slightly different spot or modulating it to simulate an engine turning on and off.

In summary, the decoy mode embodiments of the invention produce sophisticated false targets that combine visual, infrared, radar, and other cues to confidently trick AI systems into detecting and misidentifying them. The decoy designs are optimized for realism in the sensor feature space and can be delivered as practical kits or instructions that field personnel or automated systems can deploy. This provides a powerful tool for diversion and confusion of enemy autonomous systems, effectively multiplying apparent targets or drawing attention away from real ones.

### Design Constraints and Safeguards

In both the stealth and decoy embodiments, the system accounts for various design constraints and includes safeguards to ensure practicality and legality of the generated solutions. For example, the disclosed configuration provides for physical realizability. The adversarial modifications recommended by the system are constrained to those that can actually be implemented on the target object or in the environment. For example, the system will not propose a pattern that requires color values outside the range of printable inks or materials that don't exist. In the optimization process (particularly for gradient-based methods), constraints are enforced so that the pattern changes remain within a feasible domain (often through clamping values or adding penalty terms for unrealistic features). If the target object is a soldier's uniform, for instance, the system ensures the pattern can be printed on fabric and endures typical wear conditions.

As part of input preferences, if there are safety or operational constraints (or limits) that the system will factor. For example, not obscuring certain sensors or markings on a friendly vehicle, or not interfering with normal operational functions of the object. The output pattern may have blank or unmodified regions if the user specified “do not cover windshield or camera lenses,” etc. In decoy mode, if a constraint was that the decoy device must be lightweight or powered by battery for a predetermined number of hours, the system will favor patterns that meet those energy and weight constraints (e.g., avoiding an overly power-hungry emitter if not necessary).

The disclosed configuration also addresses human observability constraints in stealth mode. The system may incorporate any plausibility constraints that ensure the adversarial pattern does not inadvertently signal its presence to unintended observers. Another example: the system could avoid using certain shapes or symbols in the pattern that might have cognitive meaning to humans (like recognizable logos or text), unless intentionally desired for some deception.

The system also may be configured to incorporate a verification marker or coding in the pattern that is machine-readable by friendly systems but not by enemy systems. For instance, the pattern could include a subtle QR-code-like arrangement or an infrared fluorescent marker that friendly IR cameras (tuned to it) can see, thereby confirming a friendly camouflaged asset even though an adversary AI just observes (or detects) a noise pattern. Similarly, a decoy might include a hidden identifier broadcast on a secure channel, so friendly units know it is a decoy. The system can design these markers to have minimal impact on the adversarial effectiveness. For example, it may place the code in a frequency band or modulation that enemy detectors do not use. This kind of verification and calibration component may be part of the deployment bundle. An example may include adding a small sticker or micro transmitter on the decoy that does not give it away to the adversary but allows easy verification by allies.

The output of the system is organized as a deployment bundle that contains all components necessary for field use. This structured output ensures nothing is left ambiguous. If delivered digitally to an autonomous deployment system, the bundle might be a data package with sub-files (images, CAD files, control scripts) and a manifest. If delivered to a human team, it might be a physical kit plus a manual. By structuring the output, the system supports rapid deployment and reduces the chance of error in implementation—an important practical safeguard.

By addressing these constraints in its design process, the disclosed configuration ensures that the adversarial patterns and decoys produced are enabled and described within the scope of practical implementation. The specification of these details in the design and output (rather than leaving them as afterthoughts) also satisfies the requirements of a complete written description, supporting any claims regarding such features.

### Deployment and Implementation in the Field

For a physical camouflage deployment on an object such as disguising a vehicle or equipment, the deployment may use the image files and templates from the deployment bundle, to print a camouflage pattern onto the chosen medium (vinyl wraps, fabric, paint stencils, etc.). Upon application of the output onto a physical object, a calibration tool may verify the pattern is correctly deployed. This might involve taking a test photograph and running it through a friendly detector or scanning a QR code embedded in the pattern. The verification component may include a small test pattern that the friendly device checks to ensure the main pattern alignment is correct.

Optionally, the decoy may have a feedback mechanism. For example, a camera on the decoy may capture video to feed into the system to determine if it is being detected.

### Verification and Adaptive Feedback

Given the sophisticated and dynamic nature of the adversarial patterns, having verification and feedback loops is valuable to maintain trust in the system and to continually improve it. As noted, the pattern or decoy device can include an embedded machine-readable marker or code. This could be as straightforward as a small barcode printed in an unobtrusive corner of a camouflage pattern, or a digital code broadcast by electronics of a decoy. Friendly verification devices, which may be a smartphone app or as advanced as a dedicated scanner, may detect this marker to confirm that that the pattern deployed is indeed the correct one generated by the system. This may protect against any confusion or enemy tampering. It also may determine whether alignment and orientation are correct. In the case of decoys, it may analyze whether the devices are functioning as intended.

Some embodiments include a calibration step where, for example, once a camouflage is applied, the system can take a reference photo or sensor reading of the object in the environment and run its detectors to see if anything pops out. If, say, a subtle outline was still detectable, the system might alert the user to adjust. This kind of last-mile calibration ensures that what was simulated indeed translates to reality.

After or during a mission, any available data about the adversarial pattern's performance can be looped back. For example, if a camouflaged asset remains undetected for a period, it may not yield data. However, if it did get detected or if the enemy seemed to react (maybe radio chatter intercepted about a “weird-looking pattern” or an image of it was captured), that information can be fed to the system learning module. The system may update its threat models (perhaps the enemy used a type of sensor not originally anticipated, etc.). Similarly, if a decoy successfully drew fire or attention, any recordings of how it was perceived (or registered) (radar logs, etc.) may help validate and tune the model.

In a scenario with many deployed units using adversarial patterns, a central server or distributed network could aggregate all their feedback. As mentioned earlier, this can form a collective intelligence where each engagement makes the system smarter for the next time. One can imagine after a few rounds of cat-and-mouse, a detector of the system ensemble might include versions of adversary models that have been retrained to recognize earlier patterns—and thus the system is preemptively finding new patterns to beat even those improved models. This continuous cycle ensures the invention's outputs do not become stale.

In summary, the verification and feedback capabilities of the system close the loop between design and reality, providing assurance that the deployed adversarial measures are working as intended and offering pathways to refine the system over time. This makes the invention's solutions more robust and trustworthy in critical applications.

### Example Applications and Use Cases

The adversarial camouflage and decoy generation platform described herein has broad applicability across military, security, and even some civilian domains. The following examples illustrate a range of use cases, demonstrating how the core technology can be adapted and utilized in practice. For example, they may be applied to personal stealth wearables. Military uniforms, tactical gear, or even civilian clothing for high-profile individuals could be embedded with adaptive adversarial camouflage. For instance, a cloak generated by the system might contain a pattern effective against both visible and IR detection, rendering the wearer virtually invisible to an AI-powered surveillance drone scanning for human shapes. Special forces uniforms might be printed with region-specific adversarial patterns prior to a mission, and those patterns could be updated if the mission parameters change (e.g., moving from forest to urban terrain at night).

Similarly, tanks, armored vehicles, ships, and aircraft can be covered with multispectral adversarial coatings. A naval ship, for example, might receive a paint job that not only camouflages it visually against the sea surface from aerial observation but also includes materials and textures that reduce its radar signature and thermal exhaust visibility. An unmanned aerial vehicle (UAV) could be wrapped in a pattern that confuses both computer vision and heat-seeking systems, perhaps by masking its shape against the sky and dispersing its exhaust heat. The system would tailor each pattern to the platform's unique shape and the expected detection threats (satellite imaging, coastal radars, etc. for the ship; or ground-based optical trackers for the UAV).

Fixed assets like forward operating bases, radar stations, communication towers, or critical infrastructure can be protected by adversarial camouflage nets or coverings. Suppose there is a remote air defense radar that adversaries try to locate via drone surveillance; the system could generate a pattern for netting that covers the installation, making it blend into the landscape in multiple spectra (perhaps appearing as just another patch of ground or agriculture to overhead IR/visual sensors). The net might have interwoven materials to also absorb or scatter incoming radar or LIDAR scans, truly cloaking the installation from detection.

The system may create decoy kits for common asset types. For example, a set of inflatable decoy tanks can be rapidly deployed in a field. Each decoy tank, enhanced with the system's pattern and emitter layout, might look convincingly like a real tank column to enemy reconnaissance. They could even be animated in some sense (e.g., heating up at times to mimic engine operation, or having blinking lights that a drone might confuse for active machines). This could mislead the enemy into wasting munitions on false targets or strategically misallocating forces. The decoy patterns ensure that even AI-based analysis (looking at heat distribution or radar returns) is fooled—something traditional decoys would fail at if the AI notices all tanks have identical heat blobs, for instance. Here, each decoy might have slight variations in pattern so that an AI sees them as more authentic.

A swarm of small drones can be deployed not to attack or surveil, but to serve as a distributed decoy. Using the system's orchestration, these drones could coordinate their positions and emitted signatures to simulate one or multiple larger objects. For example, at night a dozen micro-drones equipped with IR LEDs might fly in a formation that to thermal cameras looks like a convoy of soldiers moving. Or drones with speakers could create a false acoustic signature of helicopter rotors in one area while the real helicopters approach from another direction. The adversarial patterns here include the trajectories and timing for the swarm, optimized such that the combined sensor footprint matches the intended illusion. This example shows how the invention can produce not just static patterns, but dynamic, coordinated behaviors as “patterns” in time and space.

While physical domains are described, similar principles could protect digital assets. For instance, one could envision using adversarial patterns to watermark sensitive images or videos such that if they are intercepted and run through an AI (for face recognition, object detection, etc.), the AI is blinded or misled. A company might apply a nearly invisible adversarial noise pattern to its confidential video feeds so that if someone unauthorized tries to analyze them with AI, they get junk results. This is more of a defensive camouflaging in the digital space but uses the same core technology. Conversely, in intelligence operations, injecting decoy data into an AI pipeline of an adversary system, e.g., during training or in live feeds, may cause them to see threats that aren't there and react erroneously.

Through these examples, it is demonstrated how the core adversarial pattern generation technology can be applied in practice to significantly enhance stealth and deception capabilities against AI-based detection, all while accounting for human factors and practical deployment considerations. The various embodiments and use cases highlight the multi-modal effectiveness of the invention (spanning visual, thermal, radar, acoustic, etc.) and its adaptability to different operational needs.

### Computing Machine Architecture

Turning now to FIG. 5, illustrated is an ex ample machine to read and execute computer readable instructions, in accordance with an embodiment. Specifically, FIG. 5 shows a diagrammatic representation of the data processing service (and/or data processing system) in the example form of a computer system 500. The computer system 500 is structured and configured to operate through one or more other systems (or subsystems) as described herein. The computer system 500 can be used to execute instructions 524 (e.g., program code or software) for causing the machine (or some or all of the components thereof) to perform any one or more of the methodologies (or processes) described herein. In executing the instructions, the computer system 500 operates in a specific manner as per the functionality described. The computer system 500 may operate as a standalone device or a connected (e.g., networked) device that connects to other machines. In a networked deployment, the machine may operate in the capacity of a server machine or a client machine in a server-client network environment, or as a peer machine in a peer-to-peer (or distributed) network environment.

The computer system 500 may be a server computer, a client computer, a personal computer (PC), a tablet PC, a smartphone, an internet of things (IoT) appliance, a network router, switch or bridge, or other machine capable of executing instructions 524 (sequential or otherwise) that enable actions as set forth by the instructions 524. Further, while only a single machine is illustrated, the term “machine” shall also be taken to include any collection of machines that individually or jointly execute instructions 524 to perform any one or more of the methodologies discussed herein.

The example computer system 500 includes a processor system 502. The processor system 502 includes one or more processors. The processor system 502 may include, for example, a central processing unit (CPU), a graphics processing unit (GPU), neural processing unit (NPU), a tensor processing unit (TPU), a digital signal processor (DSP), a controller, a state machine, one or more application specific integrated circuits (ASICs), one or more radio-frequency integrated circuits (RFICs), or any combination of these. The processor system 502 executes an operating system for the computing system 500. The computer system 500 also includes a memory system 504. The memory system 504 may include or more memories (e.g., dynamic random-access memory (RAM), static RAM, cache memory). The computer system 500 may include a storage system 516 that includes one or more machine readable storage devices (e.g., magnetic disk drive, optical disk drive, solid state memory disk drive).

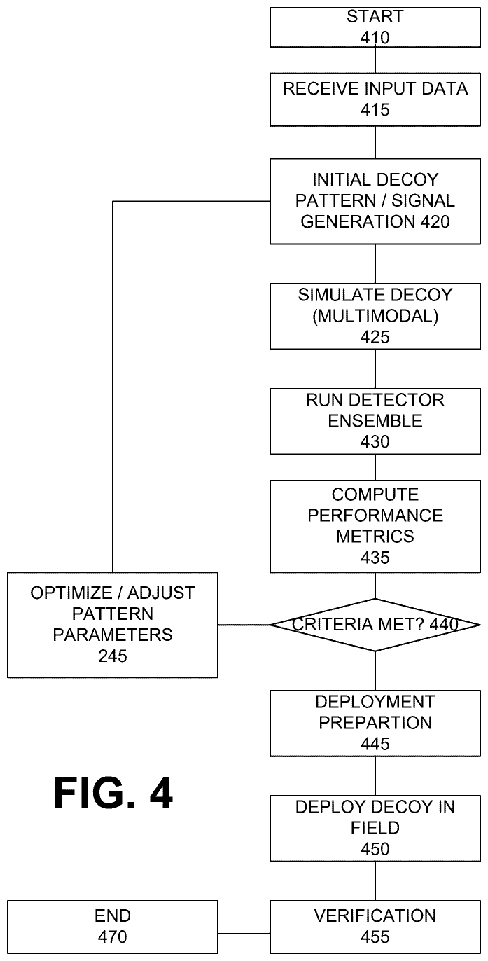

The storage unit 516 stores instructions 524 (e.g., software) embodying any one or more of the methodologies or functions described herein. For example, the instructions 524 may include instructions to perform the functional operation of the processes described with FIGS. 1A through 4. The instructions 524 may also reside, completely or at least partially, within the memory system 504 or within the processing system 502 (e.g., within a processor cache memory) during execution thereof by the computer system 500, the main memory 504 and the processor system 502 also constituting machine-readable media. The instructions 524 may be transmitted or received over a network 526, such as the network 526, via the network interface device 520.

The storage system 516 should be taken to include a single medium or multiple media (e.g., a centralized or distributed database, or associated caches and servers communicatively coupled through the network interface system 520) able to store the instructions 524. The term “machine-readable medium” shall also be taken to include any medium that is capable of storing instructions 524 for execution by the machine and that cause the machine to perform any one or more of the methodologies disclosed herein. The term “machine-readable medium” includes, but not be limited to, data repositories in the form of solid-state memories, optical media, and magnetic media.

In addition, the computer system 500 can include a display system 510. The display system 510 may drive firmware (or code) to enable rendering on one or more visual devices, e.g., drive a plasma display panel (PDP), a liquid crystal display (LCD), or a projector. The computer system 500 also may include one or more input/output systems 512. The input/output (IO) systems 512 may include input devices (e.g., a keyboard, mouse (or trackpad), a pen (or stylus), microphone) or output devices (e.g., a speaker). The computer system 500 also may include a network interface system 520. The network interface system 520 may include one or more network devices that are configured to communicate with an external network 526. The external network 526 may be a wired (e.g., ethernet) or wireless (e.g., Wi-Fi, BLUETOOTH, near field communication (NFC).

The processor system 502, the memory system 504, the storage system 516, the display system 510, the IO systems 512, and the network interface system 520 are communicatively coupled via a computing bus 508.

### First Example Systems

The disclosure includes a first embodiment of system (including its processes) to generate an adversarial pattern (e.g., a visual or non-visual one) to reduce the detectability of a physical target object by one or more machine perception systems the system receives an input comprising a representation of the target object, a stealth objective to minimize the object's detectability, and context data describing anticipated sensor modalities and environmental conditions. The system produces one or more candidate camouflage patterns for application to the target object. Each candidate may be generated by an algorithmic process and incorporating features selected to blend with the environment or disrupt recognition features of the target object. The system virtually applies each candidate camouflage pattern to a model of the target object and simulating the appearance or signature of the patterned object in a multi-modal sensor environment corresponding to the anticipated sensor modalities. For each simulated candidate, the system evaluates detection outputs from a set of machine-learned object detection models (a detector ensemble) covering the sensor modalities, The detection outputs indicating whether the patterned object would be detected by each model. The systems computes a stealth performance metric for each candidate based on the detection outputs. The metric decreases as the likelihood of the target object being detected by the models decreases, The system iteratively adjusts the candidate patterns to improve the stealth performance metric by selectively modifying pattern characteristics and re-evaluating, thereby searching for a pattern that yields minimal detection across the detector ensemble. Upon identifying an optimized camouflage pattern that meets a predefined low-detectability criterion against the detector ensemble, the system generates an output package. The output package may be a representation of the optimized pattern configured for application to the physical target object. It also may include deployment instructions specifying how to apply the pattern to the target object. When the optimized camouflage pattern is applied to the target object in the real world, the target object's detectability by the machine perception systems is substantially reduced without introducing conspicuous visual anomalies to human observers.

In a second embodiment, a system (including its processes) generates an adversarial decoy pattern or signal to induce a false target detection by machine perception systems. The system receives an input comprising a specification of a target object type or signature to mimic as a decoy, a decoy objective to cause detection of said target type where no actual such target is present, and context data describing environmental conditions and sensor types of the machine perception systems to be deceived. The system generates one or more candidate decoy patterns or multi-sensor signal configurations designed to be deployed on a decoy medium or apparatus, each candidate being formulated by an AI-driven generation process to produce sensor cues resembling the specified target type. For each candidate, the system simulates a scenario in which the candidate decoy pattern or signal is deployed in the given environment on a placeholder object or region and generates simulated sensor data for the relevant sensor types (including at least one of visual, infrared, or radar) as if the decoy were present. The system processes the simulated sensor data through one or more object detection or recognition models corresponding to the sensor types and obtains detection results indicating whether the specified target type would be reported as present. The systems computes a decoy performance metric for each candidate based on the detection results. The metric increases according to the confidence or consistency with which the detection models erroneously indicate the presence of the target object type in the simulation. The system automatically refines the candidates in an iterative loop to improve the decoy performance metric, including modifying pattern or signal parameters and re-testing, until an optimized decoy pattern or configuration is identified that causes the detection models to meet or exceed a desired false-detection confidence level. The system generates (or outputs) the optimized decoy design in a deployment format. The deployment format may be a pattern data or device control instructions for implementing the decoy on a physical decoy apparatus or injecting it into a sensor stream. The deployment format also may include guidelines for placement or activation of the decoy to maximize its effectiveness. Deployment of the optimized decoy pattern (which may be a signal) in the field causes the machine perception systems to detect and classify a phantom target corresponding to the specified target type, thereby diverting or misdirecting an advertising attention or resources.

In the first or the second embodiment, the input context parameters include a multi-sensor threat profile specifying a set of diverse sensor modalities and associated detection algorithms to counter. The process of simulated representations with the ensemble of object detection models may use detectors. The detectors may be, for example, visible-spectrum image classifiers or object detectors, low-light or night-vision imaging detectors, thermal infrared object detectors, LiDAR-based object recognizers or point cloud analyzers, radar signal detection or tracking algorithms, and acoustic event detection models. The sensors may be used to evaluate each candidate adversarial pattern against a comprehensive range of sensor-based detection threats.

Also in the first or the second embodiment, the initial candidate patterns or signals may use a machine-learning generative model conditioned on contextual data so as to bias candidates toward plausible patterns given the environment or target characteristics, including: for a camouflage objective, incorporating colors, textures, or shapes found in the surrounding environment of the target object; and for a decoy objective, incorporating features characteristic of the intended false target (including expected shape outlines, thermal hotspots, or radar reflective elements associated with that target type).

Further in the first or the second embodiment, a system may simulate the representation of the target object with each candidate includes creating a digital model (e.g., a three-dimensional (3D) digital model or digital twin) of the target object (or a surrogate object for a decoy) and virtually apply the candidate pattern to said model. The system may simulate rendering the model in a plurality of scenes or viewpoints with varying angles, distances, and lighting or background conditions to test robustness of each candidate adversarial pattern under different real-world conditions.

Also in the first or second embodiment, the system may evaluate the adversarial performance metric comprises. The system may obtain from each detector in the ensemble a confidence score or detection decision regarding the presence of the target object (or specified decoy target type), and computing the metric. For example, for a stealth camouflage objective, the performance metric is lower (e.g., better) when the detectors' confidence in detecting the target object is lower, and can be defined, for example, as a negative weighted sum or maximum of the detection confidence scores across the ensemble. For a decoy objective, the performance metric is higher (e.g., better) when the detectors indicate a false target, and may be defined as a positive function of the confidence scores for detecting the specified target type across the ensemble. The system optimization may include minimizing the performance metric in stealth mode or maximize the performance metric in decoy mode, respectively, in order to converge on an effective adversarial solution.

Also in the first or the second embodiment, the iterative optimization loop may employ an evolutionary algorithm, maintain a population of candidate patterns, select a subset of high-perform candidates as parents, and generate a next generation of candidate patterns by recombining or mutating features of the parents. Hence, adversarial patterns may be progressively evolved to satisfy the stealth or decoy objective over successive generations. In addition, when the iterative optimization loop employs a reinforcement learning agent that incrementally modifies a pattern and receives a reward signal based on the adversarial performance metric for that pattern, the agent may learn through trial-and-error to construct patterns yielding high rewards (corresponding to effective reduction of detectability or successful decoying).

The first or the second embodiment also may perform a human-observability constraint check on candidate patterns during each iteration. The adversarial pattern candidates that contain visually conspicuous or contextually implausible features, e.g., as determined by predefined heuristics or by evaluating the pattern with a model of human perception), are filtered out or penalized in the performance metric to help ensure that the optimized adversarial pattern remain inconspicuous or plausible to human observers in the deployment environment while deceiving machine detectors.

The systems also may update the detector ensemble or retrain the generative models in response to newly obtained data about adversary detection algorithms or environmental changes. This enables the optimization to adapt to evolving sensor threats over time and can produce updated adversarial patterns as needed.

The first embodiment or the second embodiment may as part of the system output, transmit the optimized adversarial pattern data and associated deployment instructions to a remote user device or deployment system via a network interface, thereby enabling the adversarial pattern to be delivered as a service output for deployment at a separate location or by end-users in the field.

With a stealth system, the optimized adversarial camouflage pattern may be tailored to multiple sensor modalities. When applied, the target object's visual appearance, thermal emission, and one or more additional signatures (radiofrequency, acoustic, etc.) are all altered in concert to reduce overall detectability, and wherein the outputting step includes providing a deployment bundle containing the pattern application instructions and any specified supplementary materials or devices (including thermal insulation patches, radar-absorbing elements, or sound-damping components) to achieve the intended multi-modal stealth effect.

With a decoy system, the optimized adversarial decoy configuration may include a coordinated arrangement of multi-modal emission sources and pattern elements such that the combination simulates the signature of the target object type, and wherein the outputting step includes instructions for orchestrating multiple devices or components. For example, it may position visual decoy objects, activate timing for infrared or radar emitters, and spatially arrange reflectors to collectively produce a convincing false target signature.

### Second Example Systems

A first embodiment includes a system for generating adaptive multi-modal adversarial camouflage and decoy patterns. One or more processors and memory store program instructions executable by the processors. The program instructions may be structured as modules. A system may include a pattern generation module that is configured to synthesize candidate adversarial patterns or signal configurations for a target object based on input objectives and context parameters. A simulation module may be configured to virtually apply each candidate pattern to a representation of the target object and to render simulated sensor data for one or more sensor modalities representing how the target object would be registered with the pattern. A detector ensemble module may include a plurality of object detection models for different sensor modalities. The detector ensemble module may be configured to process the simulated sensor data and produce detection outputs indicative of a presence or absence of the target object (or specified decoy target) according to each model. An optimization module may be configured to receive the detection outputs for the candidates and automatically adjusts the candidate patterns through an iterative feedback loop. It may utilize machine learning or evolutionary optimization techniques to improve pattern effectiveness with respect to reducing detectability or inducing false detection. An output compiler module may be configured to format a resulting optimized adversarial pattern or signal configuration into a deployable form, including generating any necessary physical pattern files, device control instructions, or application guidelines. They system may further be configured such that the optimized adversarial pattern or signal deceives a plurality of different sensor-type detectors simultaneously, thereby providing an adaptive stealth or decoy solution against multi-modal machine perception threats.

The pattern generation module may be further configured to synthesize candidate adversarial patterns using one or more of: a machine-learning-based generator. It may include a generative adversarial network or other neural synthesis model trained to produce environment-blended camouflage patterns or a procedural pattern library. The optimization module may be operatively coupled to the pattern generation module to update or refine generated candidates. It may include, for example, backpropagating adversarial feedback into a neural generator or selecting and recombining pattern candidates as part of the iterative optimization process.

The detector ensemble module may further include at least one of a deep neural network vision detector for analyzing visible-spectrum imagery, a thermal infrared object detector for analyzing heat signature data, and a radar or LiDAR-based object detection algorithm for analyzing active sensor returns. The system may evaluate candidate patterns on at least these three different types of sensor data concurrently to ensure cross-modality effectiveness.

The simulation module may further be configured to include a physics-based renderer or sensor signal emulator that can simulate, for the target object with a given pattern: visual scenes under various lighting conditions, infrared thermal images based on heat transfer models, LiDAR point clouds or depth maps, and radar cross-section responses, thereby generating realistic multi-modal sensor inputs for the detector ensemble during training and optimization.

The output compiler module may be further configured to interface with manufacturing or deployment hardware. Upon obtaining the optimized adversarial pattern, it may determine if the pattern is to be applied physically to an object. The system can send the pattern data to a connected fabrication device or printer to produce the physical patterned material or can transmit instructions to an electronic display on the object to display the pattern. If the pattern involves active signal emissions, the system may program one or more emission devices with the optimized signal parameters (including timing, intensity, frequency, or waveform), thereby automating the deployment of the adversarial effect according to the optimized design.

A deployment feedback interface module may be configured so that during or after deployment of an adversarial pattern, it collects data from real-world performance, including sensor readings or detection outcomes observed when the pattern is in use. Optionally, a learning module may use this feedback to update the pattern generation module or detector models whereby the system continuously adapts its output patterns over time to maintain effectiveness as conditions or adversary detectors evolve.

The disclosed system may be configured in a distributed architecture with components deployed on multiple platforms. There may be multiple instances of the system on different assets share information about pattern performance and threat updates via a network to allow collaborative improvement and consistency of adversarial patterns across a fleet of protected or decoy-equipped assets.

### Third Example Systems

An adversarial pattern product may be an article of manufacture that embodies an optimized adversarial design configured to modulate a target object detectability by an AI-based detection system. The article is characterized by machine-perceptible features that are adversarial effective with respect to at least one sensor modality, but appear contextually inconspicuous or plausible to a human observer.

The article is configured such that when the article is a physical patterned material applied to or integrated with a target object, the presence of the target object is rendered less detectable or differently detectable by the AI-based detection system. This may include making a real object significantly less likely to be detected or making a non-target object appear as a target as a result of the adversarial pattern on the material. When the article is a data artifact or signal configuration, for example, a printed image, a projected display, an electronic signal file, or an arrangement of emitters that corresponds to the adversarial pattern, the artifact or configuration is usable to deploy said pattern onto a target object or into a sensor data stream so as to achieve the intended adversarial effect on the detection system.

The physical patterned material may selected from one or a camouflage wrap or coating applied to a vehicle or equipment, a printed textile integrated into apparel or gear, an adhesive decal or laminate for attaching to an object's surface, or a three-dimensional cover or shell with a surface pattern, the material bearing an adversarial camouflage pattern optimized for a particular environment and threat profile.

When the adversarial pattern is embedded in or applied to a digital medium it may be processed by an object-detecting algorithm, the algorithm is deceived with respect to a particular object's presence or identity, thereby providing a digital camouflage or decoy effect, including causing the algorithm to miss a real object in the scene or hallucinate a false object in the scene.

The article may include a verification and calibration component associated with the adversarial pattern. The pattern or associated device may include a machine-readable marker or an encoded signal (or an internal self-test routine) that can be used by friendly systems to verify that the pattern is correctly deployed and functioning as intended, without substantially compromising the pattern's effectiveness against adversary detectors.

When the article is a decoy device or kit, it may include a structural substrate or form factor resembling a target object and one or more emission or reflection components (such as thermal emitters, light projectors, radar reflectors, or speakers) arranged according to the optimized adversarial pattern, such that when the decoy device is deployed and the components are activated, the device produces multi-modal sensor signatures that mimic those of the target object to an AI detector.

### Additional Configuration Considerations

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of components, modules, or mechanisms. Modules may constitute either software modules (e.g., code embodied on a machine-readable medium and processor executable) or hardware modules. A hardware module is tangible unit capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as a hardware module that operates to perform certain operations as described herein.

In various embodiments, a hardware module may be implemented mechanically or electronically. For example, a hardware module is a tangible component that may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

The performance of certain of the operations may be distributed among the one or more processors, not only residing within a single machine, but deployed across a number of machines. In some example embodiments, the one or more processors or processor-implemented modules may be located in a single geographic location (e.g., within a home environment, an office environment, or a server farm). In other example embodiments, the one or more processors or processor-implemented modules may be distributed across a number of geographic locations.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

Upon reading this disclosure, those of skill in the art will appreciate additional alternative structural and functional designs for a system and a process for an adversarial modulation of machine perception through the disclosed principles herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

What is claimed is:

1. A non-transitory computer readable storage medium comprising stored instructions executable by a processing system of a computer system to generate an adversarial pattern, the instructions when executed causes the computer system to:
receive an input specifying (i) data describing a target object, (ii) an objective indicating whether to reduce detectability of the target object or to induce a false detection of a target type, and (iii) one or more context parameters;
generate a plurality of candidate adversarial patterns for the target object using an AI-based generative algorithm, each candidate adversarial pattern representing a potential solution for achieving the objective under the or more context parameters;
simulate a representation of the target object with candidate adversarial pattern in a virtual environment that models a plurality of sensor modalities, the simulation processed through a plurality of machine learning object detection models;
analyze detectability or recognizability of the target object with candidate adversarial pattern by a machine perception system;
generate, for each target object with candidate adversarial pattern, a performance metric to rank the candidate adversarial pattern based on an effectiveness of the simulated representation; and
generate as an optimized adversarial pattern the candidate adversarial pattern with highest rank.

2. The non-transitory computer readable storage medium of claim 1, wherein the machine perception system comprises at least one of a visual-spectrum sensor and a non-visual sensor.

3. The non-transitory computer readable storage medium of claim 1, wherein the performance metric is formulated for the candidate adversarial pattern according to one of:
for a stealth objective, decrease the detectability of the target object; and
for a decoy objective, induce a false positive detection of the target object.

4. The non-transitory computer readable storage medium of claim 1, wherein the instructure to generate the performance metric to rank the effectiveness of the simulated representation further comprises instructions to optimize automatically the candidate adversarial pattern via an iterative feedback loop in response to its performance metrics, the feedback loop comprising instructions to apply at least one of an evolutionary algorithm operation, a reinforcement learning update, or gradient-based adjustment to improve performance with respect to subsequent simulations.

5. The non-transitory computer readable storage medium of claim 4, further comprising instructions to repeat the instructions to simulate, analyze, and the generate until the optimized adversarial pattern satisfies one of a detectability of the target object falling below a threshold level or a confidence of a detection of the target object exceeding a threshold level.

6. The non-transitory computer readable storage medium of claim 1, further comprising instructions to generate the optimized adversarial pattern in a deployment ready format, the deployment ready format comprising data and instructions to deploy the optimized adversarial on the target object to cause machine perception systems to at least one of inaccurately detect, classify, detect the target object.

7. The non-transitory computer readable storage medium of claim 1, wherein the instructions to simulate the representation of the target object with candidate adversarial pattern for each candidate adversarial pattern further comprises instructions to:
create a digital model of the target object;
apply the candidate pattern to the digital model; and
render the model in a plurality of scenes or viewpoints at least one of varying angles, distances, lighting, or background conditions to test robustness of each candidate adversarial pattern under differing real-world conditions.

8. A computer-implemented method to generate an adversarial pattern, the method comprising:
receiving an input specifying (i) data describing a target object, (ii) an objective indicating whether to reduce detectability of the target object or to induce a false detection of a target type, and (iii) one or more context parameters;
generating a plurality of candidate adversarial patterns for the target object using an AI-based generative algorithm, each candidate adversarial pattern representing a potential solution for achieving the objective under the or more context parameters;
simulating a representation of the target object with candidate adversarial pattern in a virtual environment that models a plurality of sensor modalities, the simulation processed through a plurality of machine learning object detection models;
analyzing detectability or recognizability of the target object with candidate adversarial pattern by a machine perception system;
generating, for each target object with candidate adversarial pattern, a performance metric for ranking the candidate adversarial pattern based on an effectiveness of the simulated representation; and
generating as an optimized adversarial pattern the candidate adversarial pattern with highest rank.

9. The method of claim 8, wherein the machine perception system comprises at least one of a visual-spectrum sensor and a non-visual sensor.

10. The method of claim 9, wherein the performance metric is formulated for the candidate adversarial pattern according to one of:
for a stealth objective, decrease the detectability of the target object; and
for a decoy objective, induce a false positive detection of the target object.

11. The method of claim 9, wherein ranking the effectiveness of the simulated representation further comprises optimizing automatically the candidate adversarial pattern via an iterative feedback loop in response to its performance metrics, the feedback loop applying at least one of an evolutionary algorithm operation, a reinforcement learning update, or gradient-based adjustment to improve performance with respect to subsequent simulations.

12. The method of claim 11, further comprising repeating the simulating, analyzing, and the generating steps until the optimized adversarial pattern satisfies one of a detectability of the target object falling below a threshold level or a confidence of a detection of the target object exceeding a threshold level.

13. The method of claim 9, further comprising generating the optimized adversarial pattern in a deployment ready format, the deployment ready format comprising data and instructions for deploying the optimized adversarial on the target object to cause machine perception systems to at least one of inaccurately detect, classify, detect the target object.

14. The method of claim 9, wherein simulating the representation of the target object with candidate adversarial pattern for each candidate adversarial pattern further comprises:
creating a digital model of the target object;
applying the candidate pattern to the digital model; and
rendering the model in a plurality of scenes or viewpoints at least one of varying angles, distances, lighting, or background conditions to test robustness of each candidate adversarial pattern under differing real-world conditions.

15. A system comprising,
a processing system comprising one or more processors;
a memory comprising stored instructions to generate an adversarial pattern, the instructions when executed by the processing system causes the processing system to:
receive an input specifying (i) data describing a target object, (ii) an objective indicating whether to reduce detectability of the target object or to induce a false detection of a target type, and (iii) one or more context parameters;
generate a plurality of candidate adversarial patterns for the target object using an AI-based generative algorithm, each candidate adversarial pattern representing a potential solution for achieving the objective under the or more context parameters;
simulate a representation of the target object with candidate adversarial pattern in a virtual environment that models a plurality of sensor modalities, the simulation processed through a plurality of machine learning object detection models;
analyze detectability or recognizability of the target object with candidate adversarial pattern by a machine perception system;
generate, for each target object with candidate adversarial pattern, a performance metric to rank the candidate adversarial pattern based on an effectiveness of the simulated representation; and
generate as an optimized adversarial pattern the candidate adversarial pattern with highest rank.

16. The system of claim 15, wherein the machine perception system comprises at least one of a visual-spectrum sensor and a non-visual sensor.

17. The system of claim 15, wherein the performance metric is formulated for the candidate adversarial pattern according to one of: for a stealth objective, decrease the detectability of the target object, and for a decoy objective, induce a false positive detection of the target object, and wherein the instructions to generate the performance metric to rank the effectiveness of the simulated representation further comprises instructions to optimize automatically the candidate adversarial pattern via an iterative feedback loop in response to its performance metrics, the feedback loop comprising instructions to apply at least one of an evolutionary algorithm operation, a reinforcement learning update, or gradient-based adjustment to improve performance with respect to subsequent simulations.

18. The system of claim 17, further comprising instructions to repeat the instructions to simulate, analyze, and the generate until the optimized adversarial pattern satisfies one of a detectability of the target object falling below a threshold level or a confidence of a detection of the target object exceeding a threshold level.

19. The system of claim 15, further comprising instructions to generate the optimized adversarial pattern in a deployment ready format, the deployment ready format comprising data and instructions to deploy the optimized adversarial on the target object to cause machine perception systems to at least one of inaccurately detect, classify, detect the target object.

20. The system of claim 15, wherein the instructions to simulate the representation of the target object with candidate adversarial pattern for each candidate adversarial pattern further comprises instructions to:
create a digital model of the target object;
apply the candidate pattern to the digital model; and
render the model in a plurality of scenes or viewpoints at least one of varying angles, distances, lighting, or background conditions to test robustness of each candidate adversarial pattern under differing real-world conditions.
